(19) United States
(12) Patent Application Publication
(10) Pub. No.: US 2009/0025960 A1
(43) Pub. Date: Jan. 29, 2009

(54) CABLE-TYPE COMPOSITE PRINTED WIRING BOARD, CABLE COMPONENT, AND ELECTRONIC DEVICE

(76) Inventor: Hitoshi KASHIO, Osaka (JP)

Correspondence Address: BIRCH STEWART KOLASCH & BIRCH, PO BOX 747, FALLS CHURCH, VA, 22040-0747, US

(21) Appl. No.: 12/165,222

(22) Filed: Jun. 30, 2008

(30) Foreign Application Priority Data
Jul. 27, 2007 (JP) 2007-196334

(51) Int. Cl. H05K 1/00; H01B 3/00

(52) U.S. Cl. 174/250; 174/110 R

(57) ABSTRACT

An embodiment of the present invention is provided with a first wiring board, a cable component juxtaposed with the first wiring board, and second wiring boards laminated onto the first wiring board, which have a second conductor layer pattern connected to the cable component and a second insulating substrate. The cable component comprises a cable having a conductor wire and a sheath portion insulating the conductor wire and a planetary gear-shaped conductor wire coupler connected to the conductor wire and having conductor wire projections which, by passing through the second insulating substrate, abut against the second conductor layer pattern.

### BACKGROUND OF THE INVENTION

This application claims priority under 35 U.S.C. § 119(a) on Japanese Patent Application No. 2007-196334 filed in Japan on Jul. 27, 2007, the entire contents of which are herein incorporated by reference.

The present invention relates to a cable-type composite printed wiring board including a cable component having a coupler abutting a wiring pattern on the wiring board, a cable component suitable for use with such a cable-type composite printed wiring board, and an electronic device equipped with such a cable-type composite printed wiring board.

EMI-shielded high-frequency cable components providing three-dimensional wiring between printed boards in order to facilitate size and weight reduction and achieve high density packaging are increasingly being used in cellular phones and other small light-weight electronic devices designed for high-frequency wireless signals.

In the past, cable components equipped with connectors, such as connector-terminated cables, connector-terminated coaxial cables, and connector-terminated flexible substrates, etc., have been used for connecting printed boards to printed boards. Furthermore, rigiflex multilayer printed wiring boards, which combine flexible substrates and rigid substrates, have been used as components without connectors.

FIG. 20 is a plan elevation of a rigiflex multilayer printed wiring board according to Conventional Example 1. FIG. 21 is an enlarged end elevation showing an enlarged end elevation of a cross-section taken along arrow B-B in FIG. 20. It should be noted that hatching in the cross-section is omitted for ease of illustration.

In a nutshell, the rigiflex multilayer printed wiring board 1 according to Conventional Example 1, which is a four-layer structure, is fabricated using the following steps.

First of all, a double-sided flexible substrate (first insulating substrate 110 and first conductor layer 115) serving as an inner-layer substrate is prepared and an inner layer pattern (first conductor layer pattern 115p) is formed. Namely, the first conductor layer pattern 115p is formed on the first insulating substrate 110. It should be noted that, in the flexible region Af, the first conductor layer pattern 115p is constituted by a flexible lead pattern 115pf.

Next, a film cover layer is press-fit to the surface of the first conductor layer pattern 115p. In other words, a protective insulating layer (film cover layer) 130 (protective film 131 and protective adhesive agent 132) is formed.

Furthermore, resin-coated copper foil serving as an outer layer substrate, from which the portion corresponding to the flexible region Af is removed, is prepared and this outer layer substrate is laminated (bonded) by press lamination onto the inner layer substrate. Namely, a second insulating substrate 140 and a second conductor layer 141 are formed by lamination.

It should be noted that in some cases a single-sided rigid substrate, from which the portion corresponding to the flexible region Af is removed, is prepared as the outer layer substrate instead of the resin-coated copper foil. At such time, after preparing bonding members adapted for the single-sided rigid substrate, a single-sided rigid substrate, a bonding member, a double-sided flexible substrate, a bonding member and a single-sided rigid substrate are superposed and laminated by press lamination.

After forming the second insulating substrate 140 and second conductor layer 141, conductive through-holes 143 are formed to establish electrical continuity between the second conductor layer 141 and first conductor layer pattern 115p. Subsequently, a conductive through-hole conductor 144 is formed by copper plating the entire surface and the first conductor layer pattern 115p is connected to the second conductor layer 141.

Next, an outer layer pattern is formed by patterning the second conductor layer 141 and conductive through-hole conductor 144. In other words, a second conductor layer pattern 145 is formed. Furthermore, solder resist 150 is formed and appropriate surface treatment is carried out.

After that, the exterior shape of the flexible area Af and the exterior shape of the rigid area Ar are formed.

Upon completion of the exterior shape operation, the rigiflex multilayer printed wiring board 101 is subjected to testing.

As described above, the rigiflex multilayer printed wiring board 101 according to Prior Art Example 1 utilizes a flexible substrate as an inner layer substrate over its entire surface.

Numerous components are mounted in the rigid area Ar of the rigiflex multilayer printed wiring board 101. Namely, there is a lot of circuitry (second conductor layer pattern 145) and conductive through-holes 143, etc., and a high degree of precision in terms of smoothness (e.g. surface ridges and valleys), as well as high connection performance (e.g. restrictions on the roughness of the inner walls of the conductive through-holes, in case of which, generally speaking, the smaller the ridges and valleys on the inner walls of a conductive through-hole, the lower the fatigue of the metal of the conductive through-hole conductor and the higher the reliability), etc., are required. Moreover, high electrical performance (e.g. on-state resistance, insulation resistance), high thermal performance (e.g. solder reflow heat resistance), etc. are required as well.

In other words, in the rigid area Ar, it is preferable for the conductor to be a material of constant thickness and for the insulator to be a material of constant hardness and constant insulating properties, as well as a homogeneous material. For this reason, as a general rule, epoxy resin-impregnated glass fiber is often used.

Moreover, the flexible area Af of the rigiflex multilayer printed wiring board 101 has a lot of circuitry (flexible lead pattern 115pf) operating as leads and requires high flexural performance (e.g. bending during assembly, during closing/opening), etc.

In other words, in the flexible area Af, it is preferable for the conductor to permit processing to a constant thinness and be a material of constant flexibility and for the insulator to be a material of constant flexibility. For this reason, as a general rule, polyimide resin film, which has superior pliability and insulating properties, is often used.

However, the problem is that, due to the use of the flexible substrate as the inner substrate over the entire surface of the rigiflex multilayer printed wiring board 101 according to Prior Art Example 1, lamination is difficult to accomplish because, in the rigid area Ar, the insulator is formed as a composite material made up of a rigid insulating substrate (second insulating substrate 140) and a flexible insulating substrate (first insulating substrate 110).

Another problem is that, due to the fact that the rigid area Ar is formed from a composite material, it is difficult to form the conductive through-holes 143, and the electroplating process required for forming the conductive through-hole conductor presents difficulties as well. Other problems include the high hygroscopicity and poor thermal performance due to the fact that the rigid area Ax contains a flexible insulating substrate (e.g. a polyimide resin film).

Furthermore, there are other problems that exist which relate to the fact that the thickness of the conductor of the rigid area Ar (second conductor layer 141) and that of the conductor of the flexible area Af (first conductor layer 115) is difficult to regulate, as well as to the fact that the quality of the material of the conductor of the rigid area Ar and that of the conductor of the flexible area Af is difficult to optimize.

In other words, the problem is that it is difficult to meet the laminated structure characteristics (rigidity in the rigid area, pliability in the flexible area, reliability, and ease of processing of the laminated structure, conductor layer characteristics, the bonding strength of the rigid area and flexible area, etc.) that are respectively required for the flexible area Af and rigid area Ar.

It should be noted that technologies have been proposed (e.g. see JP200-140213A), in which different insulating substrates are utilized in the rigid area and flexible area.

However, the problem is that in the technology described in JP2006-140213A the inner layer pattern (first conductor pattern) is formed individually in the rigid area and in the flexible area, as a result of which it is difficult to align the inner layer patterns with a high degree of precision and difficult to produce finer features and increase the density of packaging. Another problem is that the use of the flexible substrate creates difficulties in terms of impedance matching, and when a shielding layer is provided, the substrate stiffens and becomes difficult to bend, resulting in decreased flexural performance.

The use of conventional cable components will be explained next with reference to FIG. 22A-FIG. 24C.

FIG. 22A, FIG. 22B, and FIG. 22C are explanatory diagrams used to explain a printed board used in Prior Art Example 2, where FIG. 22A is a plan elevation, FIG. 22B is a side elevation in the direction of arrow B in FIG. 22A) and FIG. 22C is a side elevation illustrating a state, in which the cable component is bent in the direction of arrow Rot in FIG. 22B.

A printed board unit (combination printed board unit) is produced by interconnecting the printed boards 210 with the help of a cable component 220, and the cable component 220 is constituted by a connector-terminated coaxial cable or connector-terminated cable equipped with connectors 225.

FIG. 23A, FIG. 23B, and FIG. 23C are explanatory diagrams used to explain a printed board used in Prior Art Example 3, where FIG. 23A is a plan elevation, FIG. 23B is a side elevation in the direction of arrow B in FIG. 23A, and FIG. 23C is a side elevation illustrating a state, in which the cable component is bent in the direction of arrow Rot in FIG. 23B.

A printed board unit (combination printed board unit) is produced by interconnecting the printed boards 310 with the help of a cable component 320, and the cable component 320 is constituted by a connector-terminated flexible substrate equipped with connectors 325.

FIG. 24A, FIG. 24B, and FIG. 24C are explanatory diagrams used to explain a printed board used in Prior Art Example 4, where FIG. 24A is a plan elevation, FIG. 24B is a side elevation in the direction of arrow B in FIG. 24A, and FIG. 24C is a side elevation illustrating a state, in which the cable component is bent in the direction of arrow Rot in FIG. 24B.

A printed board unit (combination printed board unit) is produced by interconnecting the printed boards 410 with the help of a cable component 420, with the printed boards 410 constituted by rigid printed boards (rigid portions) and the cable component 420 constituted by a flexible substrate (flexible portion). In other words, the printed board unit is constituted by a rigiflex multilayer printed wiring board.

When the connection is established using a connector-terminated cable, a connector-terminated coaxial cable (Prior Art Example 2), or a connector-terminated flexible substrate (Prior Art Example 3), reliability-related problems arise due to the fact that the electrical connection becomes unstable because the electrical connection is established using connector contacts. Moreover, the problem is that the strength of the connection is unstable because the connectors are mechanically fitted. Furthermore, since the connectors are mounted to the printed boards, they require a certain footprint on the printed boards and the problem is that the surface area of the printed boards cannot be utilized to the fullest extent.

When the connection is established with the help of the flexible portion of the rigiflex multilayer printed wiring board or a connector-terminated flexible substrate (Prior Art Example 4), the problem is that the electrical properties become unstable at high frequencies because of the variation generated in the widths of the patterns and pattern intervals during the etching step employed in the formation of the flexible substrate. Moreover, problems arise in terms of electromagnetic shielding performance because unwanted radiation cannot be shielded due to the fact that structurally it is impossible to enclose the entire periphery of the signal pattern within a shielding pattern. Moreover, priority cannot be given to the electrical performance and mechanical performance of the flexible portion because the structure of the flexible portion and the inner layer structure of the rigid portion are formed from unitary conductors and insulators. Furthermore, there is the problem that arrangement based on translational movement and arrangements based on torsional movement become impossible because the connection is established using a flat flexible member.

It should be noted that while technologies have been proposed for incorporating coaxial cables into wiring boards as cable components (for instance, see JP2003-273496A and JP2004-63725A), they do not involve interconnecting wiring boards with cables, nor do they eliminate the above-described problems.

### SUMMARY OF THE INVENTION

The present invention was made with account taken of these circumstances and it is an object of the invention to provide a cable-type composite printed wiring board in which a cable component and a first wiring board are juxtaposed and a planetary gear-shaped conductor wire coupler of the cable component is brought into abutting connection with a second conductor layer pattern on second wiring boards laminated onto the first wiring board, thereby easily and firmly connecting the conductor wire (cable component) to the second conductor layer pattern, which permits a reduction in size, a reduction in thickness, and allows for free spatial configuration, makes it possible to dependably effect signal transmission, and provides high reliability of connection between the cable component and the second conductor layer pattern.

Moreover, it is another object of the present invention to provide a cable component for use with a cable-type composite printed wiring board including a first wiring board, second wiring boards, which have a second insulating substrate and a second conductor layer pattern and are laminated onto the first wiring board, and a cable component juxtaposed with the first wiring board and connected to the second conductor layer pattern, wherein there are provided a cable having a conductor wire and a sheath portion insulating the conductor wire, and a planetary gear-shaped conductor wire coupler connected to the conductor wire and having conductor wire projections which, by passing through the second insulating substrate, abut against the second conductor layer pattern, as a result of which the conductor wire can be easily and accurately connected to the second conductor layer pattern with the help of the conductor wire coupler and the conductor wire can be easily and accurately connected to the second wiring boards (second conductor layer pattern) of the cable-type composite printed wiring board.

Moreover, yet another object of the present invention is to provide an electronic device equipped with a cable-type composite printed wiring board connected to a cable component, wherein a cable-type composite printed wiring board according to the present invention is utilized as the cable-type composite printed wiring board, thereby achieving a reduction in the size and thickness of the housing, making it possible to impart it with the desired shape, and providing high reliability of connection.

The cable-type composite printed wiring board according to the present invention is a cable-type composite printed wiring board including: a first wiring board having a first insulating substrate and a first conductor layer pattern; a cable component juxtaposed with the first wiring board; and second wiring boards having a second conductor layer pattern connected to the cable component and a second insulating substrate laminated onto the first wiring board, wherein the cable component includes: a cable having a conductor wire and a sheath portion insulating the conductor wire; and a planetary gear-shaped conductor wire coupler connected to the conductor wire and having conductor wire projections which, by passing through the second insulating substrate, abut against the second conductor layer pattern.

This configuration makes it possible to bring the conductor wire projections of the conductor wire coupler into secure abutment with the second conductor layer pattern and permits easy and accurate connection of the cable component (conductor wire) to the second wiring boards. In other words, due to the fact that the conductor wire (cable component) and the second conductor layer pattern can be easily and firmly connected, a cable-type composite printed wiring board can be obtained that permits a reduction in size, a reduction in thickness, and allows for free spatial configuration, makes it possible to dependably effect signal transmission, and provides high reliability of connection between the cable component and the second conductor layer pattern.

Moreover, in the cable-type composite printed wiring board according to the present invention, the apices of the conductor wire projections are disposed at positions symmetrical with respect to the bottom portions on both sides of the conductor wire projections

Based on this configuration, the shape of the conductor wire projections can be simplified and symmetry can be maintained even when the conductor wire coupler is rotated, thereby permitting easy mounting of the conductor wire coupler.

Moreover, in the cable-type composite printed wiring board according to the present invention, the number of the conductor wire projections is an even number.

When the second wiring boards are disposed symmetrically on both sides of the first wiring board, this configuration makes it possible to bring the conductor wire projections into abutment with the second wiring board on both sides in a symmetric fashion and achieve identical connection characteristics.

Moreover, in the cable-type composite printed wiring board according to the present invention, the conductor wire projections are disposed such that the angle of intersection of the plane defined by the conductor wire projections and the plane of the second conductor layer pattern is not more than 90 degrees.

This configuration permits prevention of the bending, etc. of the conductor wire projections, or leakage of pressure on the conductor wire projections when the second wiring boards are laminated onto the first wiring board and conductor wire coupler, which makes it possible to bring the conductor wire coupler into secure abutment with the second conductor layer pattern.

Moreover, in the cable-type composite printed wiring board according to the present invention, the number of the conductor wire projections is a number of not less than 6.

This configuration permits stabilization of the positional relationship of the conductor wire projections in respect to the second conductor layer pattern at small angles of rotation and makes it possible to easily and securely bring the conductor wire projections into abutment with the second conductor layer pattern.

Moreover, in the cable-type composite printed wiring board according to the present invention, the conductor wire coupler is shaped as a helical gear.

This configuration makes it possible to minimize the stress whereby the conductor wire coupler tends to rotate needlessly in the direction of stabilization when the second wiring boards are laminated onto the first wiring board and conductor wire coupler, which makes it possible to easily and securely position the conductor wire coupler (conductor wire projections).

Moreover, in the cable-type composite printed wiring board according to the present invention, the obliqueness of the helical gear-shaped apices of the conductor wire coupler with respect to the thickness of the conductor wire coupler in the length direction of the conductor wire is equal to or greater than the inter-apex pitch.

This configuration makes it possible to impart a cylindrical shape to the surface defined by the apices of the conductor wire coupler, as a result of which the conductor wire projections can be brought into secure abutment with the second conductor layer pattern at any position in the thickness direction of the conductor wire coupler and the conductor wire coupler (conductor wire projections) can be easily and securely positioned.

Moreover, in the cable-type composite printed wiring board according to the present invention, the conductor wire projections are triangular in shape.

This configuration makes it possible to easily and accurately form the conductor wire projections.

Moreover, in the cable-type composite printed wiring board according to the present invention, there is formed a resin encapsulation portion encapsulating the end face of the conductor wire coupler in the length direction of the conductor wire.

This configuration permits secure encapsulation of the portion in which the conductor wire coupler is joined to the conductor wire and permits improvements in the mechanical strength and reliability of the conductor wire coupler.

Moreover, in the cable-type composite printed wiring board according to the present invention, the resin encapsulation portion is spherical in shape.

This configuration makes it possible to maintain the shape of the resin encapsulation portion constant relative to the first wiring board and second wiring boards even if the cable component rotates, and the coupling of the cable component to the first wiring board and second wiring boards can be accomplished in an easy and reliable manner.

Moreover, in the cable-type composite printed wiring board according to the present invention, the outer periphery of the resin encapsulation portion is disposed closer to the conductor wire than to the bottom portions of the conductor wire projections.

Using this configuration, the encapsulant resin can be prevented from filling the spaces between the conductor wire projections during the formation of the encapsulant resin portion and cable components can be formed at high yields.

Moreover, in the cable-type composite printed wiring board according to the present invention, the cable has a shielding wire arranged on the outer periphery of the sheath portion and an outer sheath portion sheathing the shielding wire, and the cable component includes a planetary gear-shaped shielding wire coupler connected to the shielding wire and having shielding wire projections which, by passing through the second insulating substrate, abut against the second conductor layer pattern.

This configuration makes it possible to bring the shielding wire projections of the shielding wire coupler into secure abutment with the second conductor layer pattern and permits easy and accurate connection of the cable component (shielding wire) to the second wiring boards. Namely, due to the fact that the shielding wire can be easily and securely connected to the second conductor layer pattern, it becomes possible to obtain a cable-type composite printed wiring board including a cable component in which the reliability of the connection between the cable component (shielding wire) and the second conductor layer pattern is improved, the shielding properties are enhanced, and which has superior high-frequency characteristics.

Moreover, in the cable-type composite printed wiring board according to the present invention, the apices of the shielding wire projections are disposed at positions symmetrical with respect to the bottom portions on both sides of the shielding wire projections.

Based on this configuration, the shape of the shielding wire projections can be simplified and symmetry can be maintained even when the shielding wire coupler is rotated, thereby permitting easy mounting of the shielding wire coupler. Moreover, it is also possible to minimize the generation of the stress that causes the cable to rotate in different directions between the conductor wire coupler and shielding wire coupler.

Moreover, in the cable-type composite printed wiring board according to the present invention, the number of the shielding wire projections is an even number.

When the second wiring boards are disposed symmetrically on both sides of the first wiring board, this configuration makes it possible to bring the shielding wire projections into abutment with the second wiring boards on both sides in a symmetric fashion and achieve identical connection characteristics.

Moreover, in the cable-type composite printed wiring board according to the present invention, the shielding wire projections are disposed such that the angle of intersection of the plane defined by the shielding wire projections and the plane of the second conductor layer pattern is not more than 90 degrees.

This configuration permits prevention of the bending, etc. of the shielding wire projections, or leakage of pressure on the shielding wire projections when the second wiring boards are laminated onto the first wiring board and shielding wire coupler, which makes it possible to bring the shielding wire coupler into secure abutment with the second conductor layer pattern.

Moreover, in the cable-type composite printed wiring board according to the present invention, the number of the shielding wire projections is a number of not less than 6.

This configuration permits stabilization of the positional relationship of the shielding wire projections in respect to the second conductor layer pattern at small angles of rotation and makes it possible to easily and securely bring the shielding wire projections into abutment with the second conductor layer pattern.

Moreover, in the cable-type composite printed wiring board according to the present invention, the shielding wire coupler is shaped as a helical gear.

This configuration makes it possible to minimize the stress whereby the shielding wire coupler tends to rotate needlessly in the direction of stabilization when the second wiring boards are laminated onto the first wiring board and conductor wire coupler, which makes it possible to easily and securely position the shielding wire coupler (shielding wire projections).

Moreover, in the cable-type composite printed wiring board according to the present invention, the obliqueness of the helical gear-shaped apices of the shielding wire coupler with respect to the thickness of the shielding wire coupler in the length direction of the shielding wire is equal to or greater than the inter-apex pitch.

This configuration makes it possible to impart a cylindrical shape to the surface defined by the apices of the shielding wire coupler, as a result of which the shielding wire projections can be brought into secure abutment with the second conductor layer pattern at any position in the thickness direction of the shielding wire coupler and the shielding wire coupler (shielding wire projections) can be easily and securely positioned.

Moreover, in the cable-type composite printed wiring board according to the present invention, the shielding wire projections are triangular in shape.

This configuration makes it possible to easily and accurately form the shielding wire projections.

Moreover, in the cable-type composite printed wiring board according to the present invention, there is formed a resin encapsulation portion encapsulating the end face of the shielding wire coupler in the length direction of the shielding wire in resin.

This configuration permits secure encapsulation of the portion in which the shielding wire coupler is joined to the conductor wire and permits improvements in the mechanical strength and reliability of the shielding wire coupler.

Moreover, in the cable-type composite printed wiring board according to the present invention, the resin encapsulation portion is spherical in shape.

Using this configuration, the shape status of the resin encapsulation portion relative to the first wiring board and second wiring boards can be maintained constant even if the cable component rotates, and the coupling of the cable component to the first wiring board and second wiring boards can be accomplished in an easy and reliable manner.

Moreover, in the cable-type composite printed wiring board according to the present invention, the outer periphery of the resin encapsulation portion is disposed closer to the shielding wire than to the bottom portions of the shielding wire projections.

Using this configuration, the encapsulant resin can be prevented from filling the spaces between the shielding wire projections during the formation of the encapsulant resin portion and cable components can be formed at high yields.

In addition, the cable component according to the present invention cable component for use in a cable-type composite printed wiring board including: a first wiring board having a first insulating substrate and a first conductor layer pattern, second wiring boards, which have a second insulating substrate and a second conductor layer pattern and are laminated onto the first wiring board, and a cable component juxtaposed with the first wiring board and connected to the second conductor layer pattern, wherein the cable component includes: a cable having a conductor wire and a sheath portion insulating the conductor wire, and a planetary gear-shaped conductor wire coupler connected to the conductor wire and having conductor wire projections which, by passing through the second insulating substrate, abut against the second conductor layer pattern.

Using this configuration, the conductor wire can be easily and accurately connected to the second conductor layer pattern through the conductor wire coupler, which makes it possible to obtain a cable component permitting easy and accurate connection of the conductor wire to the second wiring boards (second conductor layer pattern) of the cable-type composite printed wiring board.

Moreover, in the cable component according to the present invention, the cable has a shielding wire arranged on the outer periphery of the sheath portion and an outer sheath portion sheathing the shielding wire and includes a planetary gear-shaped shielding wire coupler connected to the shielding wire and having shielding wire projections which, by passing through the second insulating substrate, abut against the second conductor layer pattern.

Using this configuration, the shielding wire can be easily and accurately connected to the second conductor layer pattern through the shielding wire coupler, which makes it possible to obtain a cable component permitting easy and accurate connection of the shielding wire to the second wiring boards (second conductor layer patterns) of the cable-type composite printed wiring board.

Moreover, in the electronic device according to the present invention, which is an electronic device equipped with a cable-type composite printed wiring board having a cable component connected thereto, the cable-type composite printed wiring board is the cable-type composite printed wiring board according to the present invention.

Using this configuration makes it possible to obtain an electronic device, in which the size and thickness of the housing can be reduced, which can be imparted with the desired shape, and in which the reliability of connections is high.

Due to the fact that the cable-type composite printed wiring board according to the present invention includes a first wiring board, a cable component juxtaposed with the first wiring board, and second wiring boards laminated onto the first wiring board and cable component, and, in addition, includes a planetary gear-shaped conductor wire coupler connected to the conductor wire and having conductor wire projections which, by passing through the second insulating substrate, abut against the second conductor layer pattern, the conductor wire projections of the conductor wire coupler can be brought into secure abutment with the second conductor layer pattern and the cable component (conductor wire) can be easily and accurately connected to the second wiring boards. In other words, the fact that the conductor wire (cable component) and the second conductor layer pattern can be easily and firmly connected, has the effect that a cable-type composite printed wiring board can be obtained that permits a reduction in size, a reduction in thickness, and allows for free spatial configuration, makes it possible to dependably effect signal transmission, and provides high reliability of connection between the cable component and the second conductor layer pattern.

Moreover, the fact that the cable component according to the present invention is adapted for use with a cable-type composite printed wiring board including a first wiring board, second wiring boards, which have a second insulating substrate and a second conductor layer pattern and are laminated onto the first wiring board, and a cable component juxtaposed with the first wiring board and connected to the second conductor layer pattern, and, in addition, including a planetary gear-shaped conductor wire coupler connected to the conductor wire and having conductor wire projections which, by passing through the second insulating substrate, abut against the second conductor layer pattern, has the effect that it becomes possible to obtain a cable component capable of easily and accurately connecting the conductor wire to the second wiring boards (second conductor layer patterns) of the cable-type composite printed wiring board.

Moreover, the fact that the electronic device according to the present invention is equipped with the cable-type composite printed wiring board according to the present invention has the effect of providing an electronic device in which the size and thickness of the housing can be reduced, which can be imparted with the desired shape, and in which the reliability of connections is high.

### BRIEF DESCRIPTION OF THE DRAWINGS

FIG. 1 is a flow chart illustrating the general flow of steps in the cable component fabrication process used to manufacture the cable component in Embodiment 1 of the present invention.

FIGS. 2A, 2B are explanatory diagrams illustrating the overall structure of the cable used in the cable component according to Embodiment 1 of the present invention, where FIG. 2A is a plan elevation and FIG. 2B is a side elevation, in which the cable illustrated in FIG. 2A is viewed in the direction of the distal end.

FIG. 3A, FIG. 3B, and FIG. 3C are explanatory diagrams illustrating the overall structure obtained when the conductor wire coupler and shielding wire coupler are connected to the cable of the cable component according to Embodiment 1 of the present invention, where FIG. 3A is a plan elevation, FIG. 3B is a cross-sectional elevation in the direction of arrow B-B in FIG. 3A, and FIG. 3C is a cross-sectional elevation in the direction of arrow C-C in FIG. 3A.

FIGS. 4A, 4B are explanatory diagrams illustrating the overall structure obtained when the resin encapsulation portion is formed by encapsulating the shielding wire coupler and conductor wire coupler connected to the cable of the cable component according to Embodiment 1 of the present invention, where FIG. 4A is a plan elevation and FIG. 4B is an end elevation of FIG. 4A viewed in the direction of the distal end.

FIG. 5A, FIG. 5B, FIG. 5C, and FIG. 5D are explanatory diagrams used to explain coupling to the second conductor layer pattern when the conductor wire coupler of the cable component according to Embodiment 1 of the present invention has four conductor wire projections, where FIG. 5A is a side elevation viewed from the side in the direction of substrate lamination, FIG. 5B is an end elevation viewed in the direction of arrow B in FIG. 5A, FIG. 5C is a side elevation viewed from the side in the direction of substrate lamination, and FIG. 5D is an end elevation viewed in the direction of arrow D in FIG. 5C.

FIG. 6A and FIG. 6B are explanatory diagrams used to explain coupling to the second conductor layer pattern when the conductor wire coupler of the cable component according to Embodiment 1 of the present invention has five conductor wire projections, where FIG. 6A is a side elevation viewed from the side in the direction of substrate lamination and FIG. 6B is an end elevation viewed in the direction of arrow B in FIG. 6A.

FIG. 7A and FIG. 7B are explanatory diagrams used to explain coupling to the second conductor layer pattern when the conductor wire coupler of the cable component according to Embodiment 1 of the present invention has five conductor wire projections, where FIG. 7A is a side elevation viewed from the side in the direction of substrate lamination and FIG. 7B is an end elevation viewed in the direction of arrow B in FIG. 7A.

FIG. 8A, FIG. 8B, FIG. 8C, and FIG. 8D are explanatory diagrams used to explain coupling to the second conductor layer pattern when the conductor wire coupler of the cable component according to Embodiment 1 of the present invention has 6 conductor wire projections, where FIG. 8A is a side elevation viewed from the side in the direction of substrate lamination, FIG. 8B is an end elevation viewed in the direction of arrow B in FIG. 8A, FIG. 8C is a side elevation viewed from the side in the direction of substrate lamination, and FIG. 8D is an end elevation viewed in the direction of arrow D in FIG. 8C.

FIG. 9A, FIG. 9B, FIG. 9C, and FIG. 9D are explanatory diagrams used to explain coupling to the second conductor layer pattern when the conductor wire coupler of the cable component according to Embodiment 1 of the present invention has 8 conductor wire projections, where FIG. 9A is a side elevation viewed from the side in the direction of substrate lamination, FIG. 9B is an end elevation viewed in the direction of arrow B in FIG. 9A, FIG. 90 is a side elevation viewed from the side in the direction of substrate lamination, and FIG. 9D is an end elevation viewed in the direction of arrow D in FIG. 9C.

FIG. 10A, FIG. 10B, FIG. 10C, and FIG. 10D are explanatory diagrams used to explain coupling to the second conductor layer pattern when the conductor wire coupler of the cable component according to Embodiment 1 of the present invention has 16 conductor wire projections, where FIG. 10A is a side elevation viewed from the side in the direction of substrate lamination, FIG. 10B is an end elevation viewed in the direction of arrow B in FIG. 10A, FIG. 10C is a side elevation viewed from the side in the direction of substrate lamination, and FIG. 10D is an end elevation viewed in the direction of arrow D in FIG. 10C.

FIG. 11A and FIG. 11B are explanatory diagrams used to explain coupling to the second conductor layer pattern when the conductor wire projections of the conductor wire coupler of the cable component according to Embodiment 1 of the present invention have a helical gear-like shape, where FIG. 11A is a side elevation viewed from the side in the direction of substrate lamination and FIG. 11B is an end elevation viewed in the direction of arrow B in FIG. 11A.

FIG. 12 is a flow chart schematically illustrating the flow of steps in the cable-type composite printed wiring board fabrication process used in Embodiment 2 of the present invention.

FIGS. 13A, 13B are explanatory diagrams illustrating the cable component prepared in the cable preparation step of the cable-type composite printed wiring board fabrication process used in Embodiment 2 of the present invention, where FIG. 13A is a plan elevation and FIG. 13B is a end elevation, as viewed in the direction of the distal end of the cable.

FIG. 14A, FIG. 14B, and FIG. 14C are explanatory diagrams illustrating the first wiring board prepared in the first wiring board preparation step of the cable-type composite printed wiring board fabrication process used in Embodiment 2 of the present invention, where FIG. 14A is a plan elevation, FIG. 14B is an end elevation illustrating the end face of a cross-section taken in the direction of arrow B-B in FIG. 14A, and FIG. 14C is an end elevation illustrating the end face of a cross-section taken in the direction of arrow C-C in FIG. 14A.

FIGS. 15A, 15B are explanatory diagrams illustrating the second wiring boards prepared in the second wiring board preparation step of the cable-type composite printed wiring board fabrication process used in Embodiment 2 of the present invention, where FIG. 15A is a plan elevation and FIG. 15B is an end elevation illustrating the end face of a cross-section taken in the direction of arrow B-B in FIG. 15A.

FIG. 16A, FIG. 16B, and FIG. 16C are explanatory diagrams illustrating a state obtained when the cable component, first wiring board, and second wiring boards are aligned in the cable component assembly step of the cable-type composite printed wiring board fabrication process used in Embodiment 2 of the present invention, where FIG. 16A is a plan elevation, FIG. 16B is a see-through side elevation showing the arrangement in a see-through manner in the direction of arrow B-B in FIG. 16A, and FIG. 16C is an end elevation illustrating the end face of a cross-section taken in the direction of arrow C-C in FIG. 16A.

FIG. 17A, FIG. 17B, and FIG. 17C are explanatory diagrams illustrating a state obtained by laminating the cable component, first wiring board, and second wiring boards in the second wiring board lamination step of the cable-type composite printed wiring board fabrication process used in Embodiment 2 of the present invention, where FIG. 17A is a plan elevation, FIG. 17B is a see-through side elevation showing the arrangement in a see-through manner in the direction of arrow B-B in FIG. 17A, and FIG. 17C is an end elevation illustrating the end face of a cross-section taken in the direction of arrow C-C in FIG. 17A.

FIG. 18A, FIG. 18B, and FIG. 18C are explanatory diagrams illustrating a state obtained when the second conductor layer pattern is formed in the second conductor layer pattern formation step of the cable-type composite printed wiring board fabrication process used in Embodiment 2 of the present invention, where FIG. 18A is a plan elevation, FIG. 18B is a see-through side elevation showing the arrangement in a see-through manner in the direction of arrow B-B in FIG. 18A, and FIG. 18C is an end elevation illustrating the end face of a cross-section taken in the direction of arrow C-C in FIG. 18A.

FIG. 19A, FIG. 19B, and FIG. 19C are explanatory diagrams illustrating a state obtained when solder resist is formed on the surface of the second wiring boards in the solder resist formation step of the cable-type composite printed wiring board fabrication process used in Embodiment 2 of the present invention, where FIG. 19A is a plan elevation, FIG. 19B is a see-through side elevation showing the arrangement in a see-through manner in the direction of arrow B-B in FIG. 19A, and FIG. 19C is an end elevation illustrating the end face of a cross-section taken in the direction of arrow C-C in FIG. 19A.

FIG. 20 is a plan elevation of a rigiflex multilayer printed wiring board according to Conventional Example 1.

FIG. 21 is an enlarged end view showing an enlarged end elevation of a cross-section taken along arrow B-B in FIG. 20.

FIG. 22A, FIG. 22B, and FIG. 22C are explanatory diagrams used to explain a printed board used in Prior Art Example 2, where FIG. 22A is a plan elevation, FIG. 22B is a side elevation in the direction of arrow B in FIG. 22A, and FIG. 22C is a side elevation illustrating a state, in which the cable component is bent in the direction of arrow Rot in FIG. 22B.

FIG. 23A, FIG. 23B, and FIG. 23C are explanatory diagrams used to explain a printed board used in Prior Art Example 3, where FIG. 23A is a plan elevation, FIG. 23B is a side elevation in the direction of arrow B in FIG. 23A, and FIG. 23C is a side elevation illustrating a state, in which the cable component is bent in the direction of arrow Rot in FIG. 23B.

FIG. 24A, FIG. 24B, and FIG. 24C are explanatory diagrams used to explain a printed board used in Prior Art Example 4, where FIG. 24A is a plan elevation, FIG. 24B is a side elevation in the direction of arrow B in FIG. 23A, and FIG. 24C is a side elevation illustrating a state, in which the cable component is bent in the direction of arrow Rot in FIG. 24B.

### DESCRIPTION OF THE PREFERRED EMBODIMENTS

Below, embodiments of the present invention are explained with reference to drawings.

### Embodiment 1

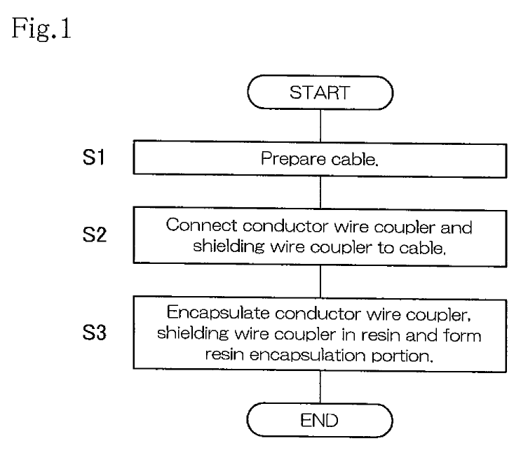

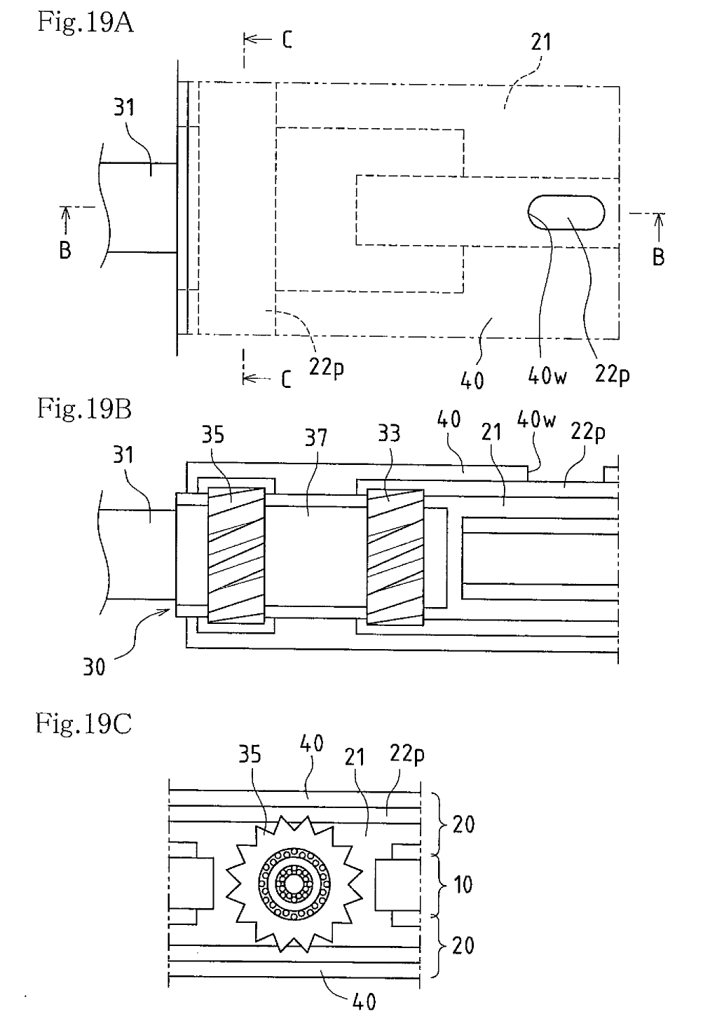

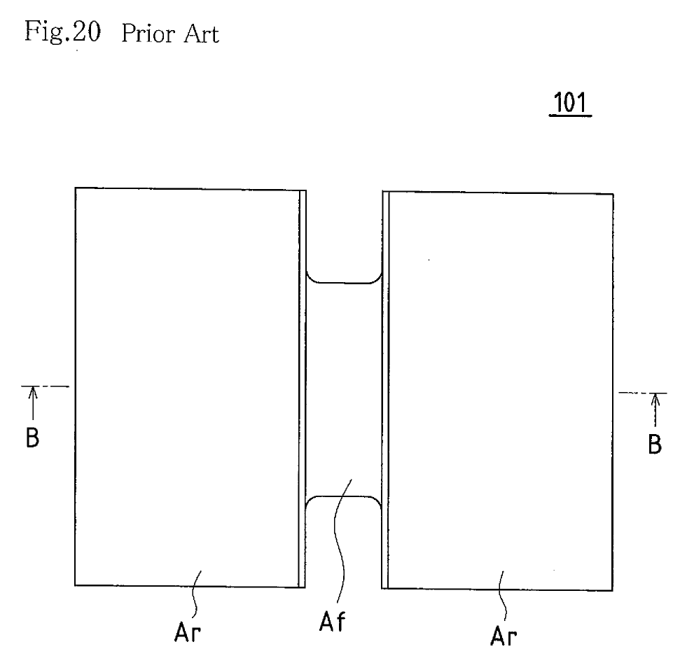

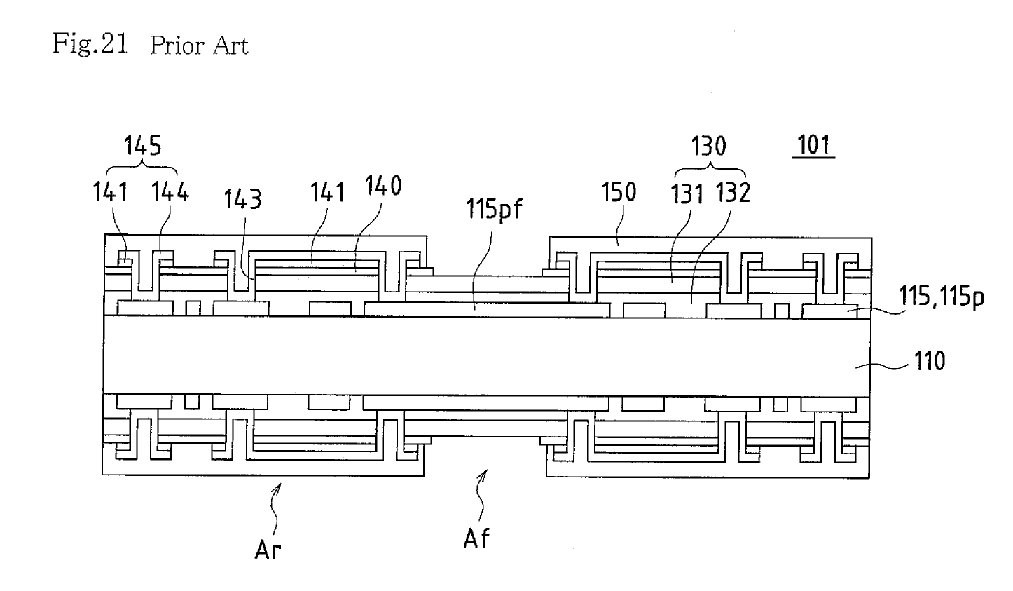

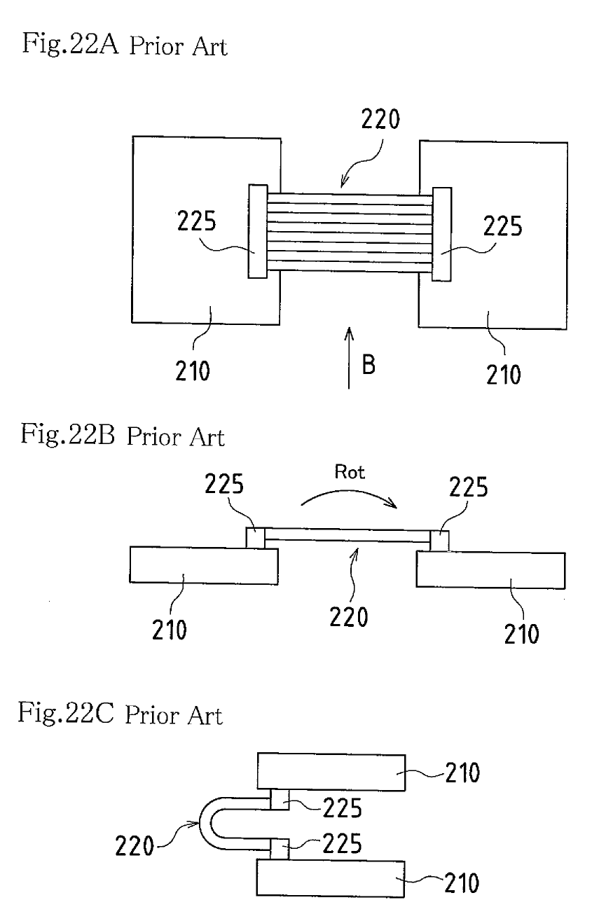

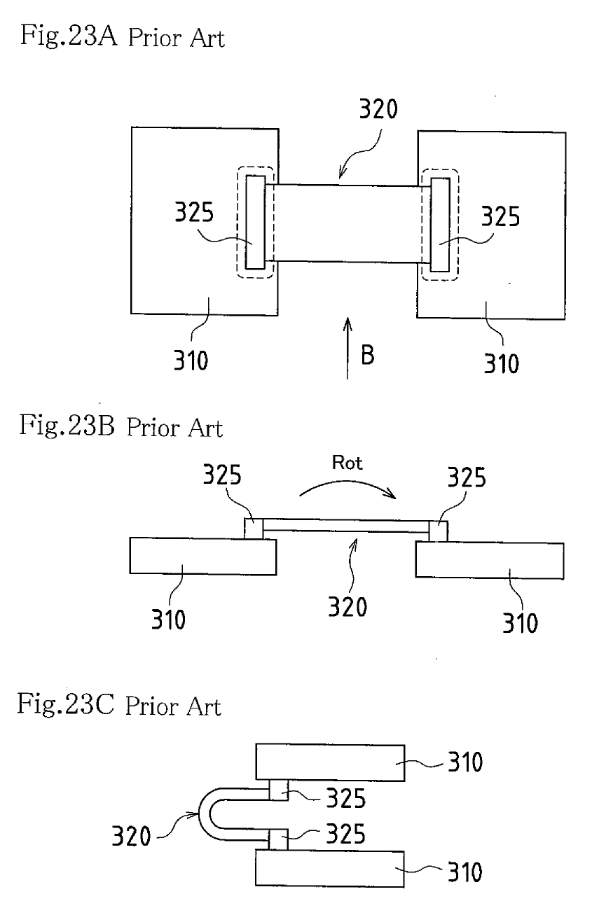

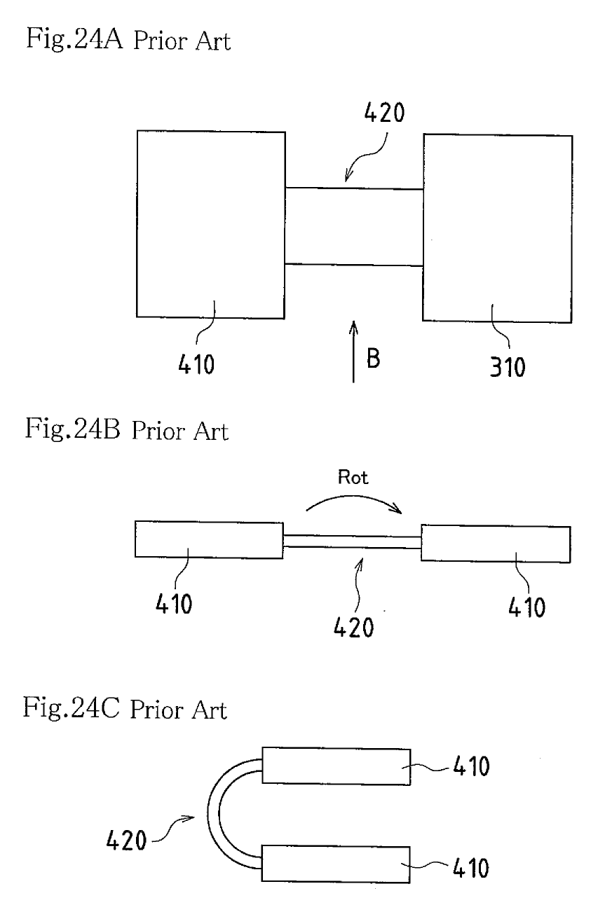

Here, FIG. 1 through FIG. 11B will be used to explain the cable component used in Embodiment 1 of the present invention and the cable component fabrication process used to manufacture the cable component. It should be noted that the cable component according to the present embodiment is suitable for use in a cable-type composite printed wiring board (see Embodiment 2, FIG. 19A, FIG. 19B, FIG. 19C) including a first wiring board 10 having a first insulating substrate 11 and a first conductor layer pattern 12p; second wiring boards 20, which have a second insulating substrate 21 and a second conductor layer 22 (second conductor layer pattern 22p) and are laminated onto the first wiring board 10; and a cable component 30, which is juxtaposed with the first wiring board 10 and connected to the second conductor layer pattern 22p.

FIG. 1 is a flow chart illustrating the general flow of steps of the cable component fabrication process used to manufacture a cable component in Embodiment 1 of the present invention.

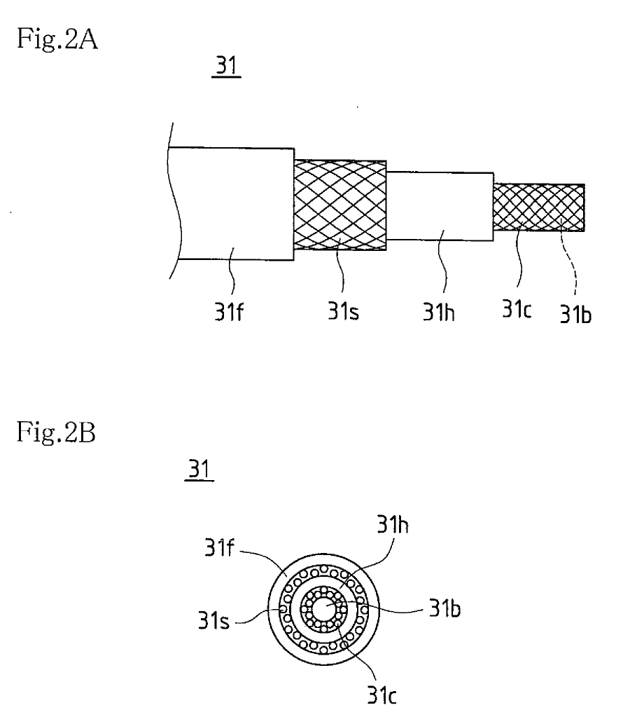

It should be noted that explanations regarding FIG. 2A through FIG. 4B, which relate to the steps (Step S1 through Step S3) of the cable component fabrication process illustrated in FIG. 1, will be provided when each step is explained.

FIGS. 2A, 2B are explanatory diagrams illustrating the overall structure of the cable used in the cable component according to Embodiment 1 of the present invention, where FIG. 2A is a plan elevation and FIG. 2B is a side elevation, in which the cable illustrated in FIG. 2A is viewed in the direction of the distal end.

Step S1:

A cable 31 is prepared, which has a conductor wire 31c and a sheath portion 31h insulating the conductor wire 31c (cable preparation step). The cable is preferably a coaxial cable further having a shielding wire 31s arranged on the outer periphery of the sheath portion 31h and an outer sheath portion 31f sheathing the shielding wire 31s. Furthermore, in the center of the structure of the cable 31, there is a core wire 31b, which possesses insulating properties and flexibility, and which makes it possible to maintain the shape of the cable, ensure flexibility and increase its strength.

The cable 31 is prepared by successively removing the outer sheath portion 31f, shielding wire 31s, and sheath portion 31h to expose the end portion of the conductor wire 31c (cable preparation step). Moreover, in the cable preparation step, the end portion of the shielding wire 31s is also exposed by further removing the outer sheath portion 31f.

The cable 31 is a coaxial cable wherein the conductor wire 31c, which serves as a signal wire, is e.g. a braided wire, and the shielding wire 31s shielding the conductor wire 31c is, e.g. a braided wire as well. As a minimum, the structure of the cable includes the conductor wire 31c and the sheath portion 31h, but it is also possible to use various other structures. Moreover, from the standpoint of cable characteristics (high-frequency characteristics), the cable preferably further includes the shielding wire 31s and outer sheath portion 31f.

The conductor wire 31c is a signal line and, therefore, desirably, has a low on-state resistance, possesses flexibility and is degradation-resistant. Suitable wires include, for instance, wires produced by tin-plating copper or a copper alloy. Moreover, the braided wire forming part of the conductor wire 31c may be an ordinary twisted wire.

The sheath portion 31h desirably possesses heat resistance, low hygroscopicity, flexibility and superior electrical properties (insulating properties). Suitable jackets include, for instance, jackets made of fluororesin.

The shielding wire 31s desirably has a low on-state resistance, possesses flexibility and is degradation-resistant. Suitable shielding wires include, for instance, shielding wires produced by tin-plating copper or a copper alloy. Moreover, the braided wire forming part of the shielding wire 31s may be an ordinary twisted wire.

It should be noted that instead of using metal wires, the conductor wire 31c and shielding wire 31s may be obtained by deposition or electroplating of wire-shaped bodies (or strip-shaped bodies) to form wire-shaped conductors.

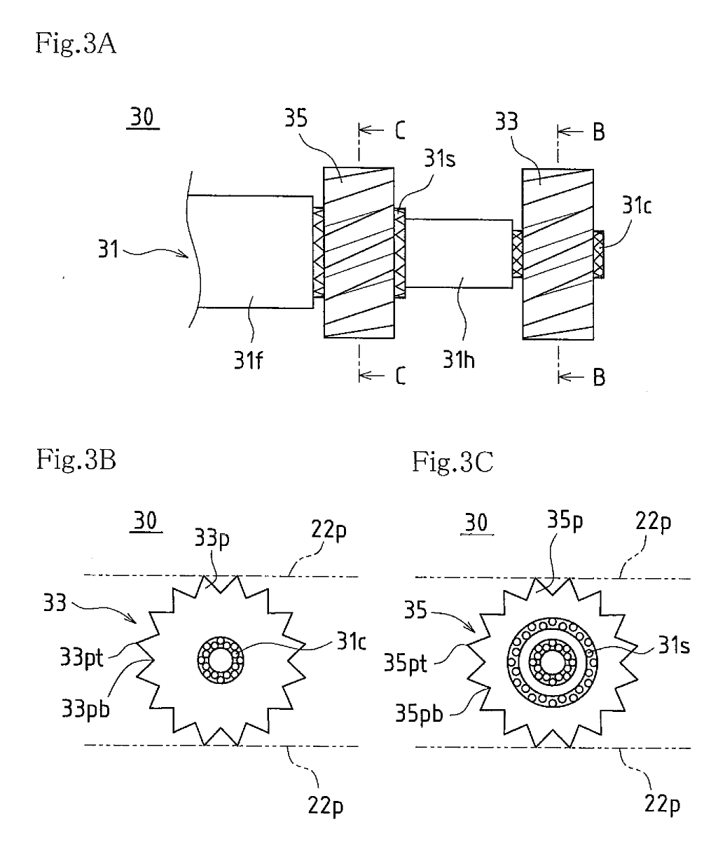

FIG. 3A, FIG. 3B and FIG. 3C are explanatory diagrams illustrating the overall structure obtained when the conductor wire coupler and shielding wire coupler are connected to the cable of the cable component according to Embodiment 1 of the present invention, where FIG. 3A is a plan elevation, FIG. 3B is a cross-sectional elevation in the direction of arrow B-B in FIG. 3A, and FIG. 3C is a cross-sectional elevation in the direction of arrow C-C in FIG. 3A. It should be noted that hatching in the cross-section is omitted for ease of illustration. Moreover, the general configuration of the second conductor layer pattern 22p is illustrated for reference purposes.

Step S2:

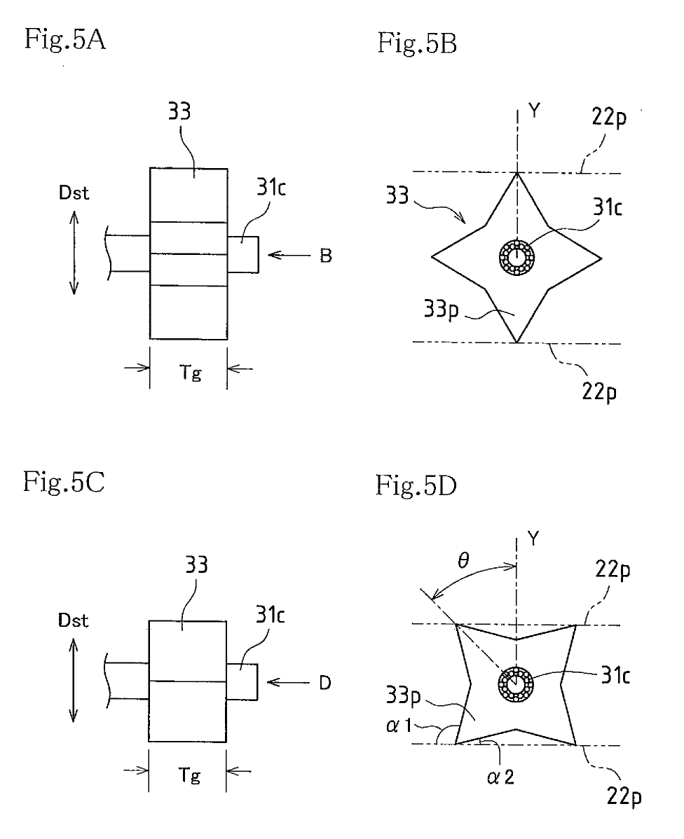

A planetary gear-shaped conductor wire coupler 33 connected to the conductor wire 31c and having conductor wire projections 33p which, by passing through the second insulating substrate 21, abut against the second conductor layer pattern 22p (obtained by patterning the second conductor layer 22 laminated onto the second insulating substrate 21 and forming part of the second wiring boards 20, see FIG. 19A, FIG. 19B, and FIG. 19A), is prepared and connected to the conductor wire 31c (coupler connection step). It should be noted that the planetary gear will be explained in detail with reference to FIG. 5A-FIG. 11B.

Moreover, a planetary gear-shaped shielding wire coupler 35 connected to the shielding wire 31s and having shielding wire projections 35p which, by passing through the second insulating substrate 21, abut against the second conductor layer pattern 22p, is prepared and connected to the shielding wire 31s (coupler connection step).

In other words, a cable component 30 includes: a cable 31 having the conductor wire 31c and the sheath portion 31h insulating the conductor wire 31c; and the conductor wire coupler 33 connected to the conductor wire 31c. Moreover, the conductor wire coupler 33 has conductor wire projections 33p which, by passing through the second insulating substrate 21, abut against the second conductor layer pattern 22p. The conductor wire projections 33p are arranged in the shape of a planetary gear.

Using this configuration, the conductor wire 31c can be easily and accurately connected to the second conductor layer pattern 22p through the conductor wire coupler 33, which makes it possible to obtain a cable component 30 permitting easy and accurate connection of the conductor wire 31c to the second wiring boards 20 (second conductor layer pattern 22p) of the cable-type composite printed wiring board.

Furthermore, the cable component 30 includes: a cable 31 having a shielding wire 31s arranged on the outer periphery of the sheath portion 31h and an outer sheath portion 31f sheathing the shielding wire 31s; and a planetary gear-shaped shielding wire coupler 35 connected to the shielding wire 31s. Moreover, the shielding wire coupler 35 has shielding wire projections 35p which, by passing through the second insulating substrate 21, abut against the second conductor layer pattern 22p. The shielding wire projections 35p are arranged in the shape of a planetary gear.

Using this configuration, the shielding wire 31s can be easily and accurately connected to the second conductor layer pattern 22p through the shielding wire coupler 35, which makes it possible to obtain a cable component 30 permitting easy and accurate connection of the shielding wire 31s to the second wiring boards 20 (second conductor layer pattern 22p) of the cable-type composite printed wiring board.

The peripheral shape (planetary gear shape) in the radial direction, as well as the arrangement of the apices 33pt and apices 35pt of the conductor wire coupler 33 and shielding wire coupler 35 with respect to the cable 31 should preferably be the same. This configuration makes it possible to minimize the generation of the stress that causes the cable 31 to rotate in different directions between the conductor wire coupler 33 and shielding wire coupler 35.

Moreover, a configuration is used, in which the conductor wire coupler 33 and shielding wire coupler 35 are formed, e.g. out of copper or a copper alloy, and their connection to the conductor wire 31c and shielding wire 31s can be accomplished in a reliable manner. Moreover, so long as the material can ensure connection to the conductor wire 31c and shielding wire 31s, it is not limited to copper and such.

The connection between the conductor wire 31c and conductor wire coupler 33 can be accomplished by passing the conductor wire 31c through e.g. a through-hole provided in the center of the conductor wire coupler 33 and bonding it by means of soldering or with an electrically conductive adhesive agent.

Moreover, the connection between the shielding wire 31s and shielding wire coupler 35 can be accomplished by passing the shielding wire 31s through e.g. a through-hole provided in the center of the shielding wire coupler 35 and bonding it by means of soldering or with an electrically conductive adhesive agent.

The connection between the conductor wire 31c and conductor wire coupler 33, as well as the connection between the shielding wire 31s and shielding wire coupler 35, can be accomplished by caulking and press-fitting without relying on solder or electrically conductive adhesive agents.

The apices 33pt of the conductor wire projections 33p are arranged in positions symmetrical with respect to the bottom portions 33pb on both sides of the conductor wire projections 33p.

For this reason, the shape of the conductor wire projections 33p can be simplified and symmetry can be maintained even when the conductor wire coupler 33 is rotated about the cable 31, thereby permitting easy and accurate mounting of the conductor wire coupler 33 (placement on the first wiring board 10 and lamination on the second wiring boards 20).

As shown in FIG. 3B, the cross-section of the conductor wire projections 33p is triangular in shape. For this reason, the conductor wire projections 33p can be formed easily and accurately.

The apices 35pt of the shielding wire projections 35p are arranged in positions symmetrical with respect to the bottom portions 35pb on both sides of the shielding wire projections 33p.

For this reason, the shape of the shielding wire projections 35p can be simplified and symmetry can be maintained even when the shielding wire coupler 35 is rotated about the cable 31, thereby permitting easy and accurate mounting of the shielding wire coupler 35 (placement on the first wiring board 10 and lamination on the second wiring boards 20).

As shown in FIG. 3C, the cross-section of the shielding wire projections 35p is triangular in shape. For this reason, the shielding wire projections 35p can be formed easily and accurately.

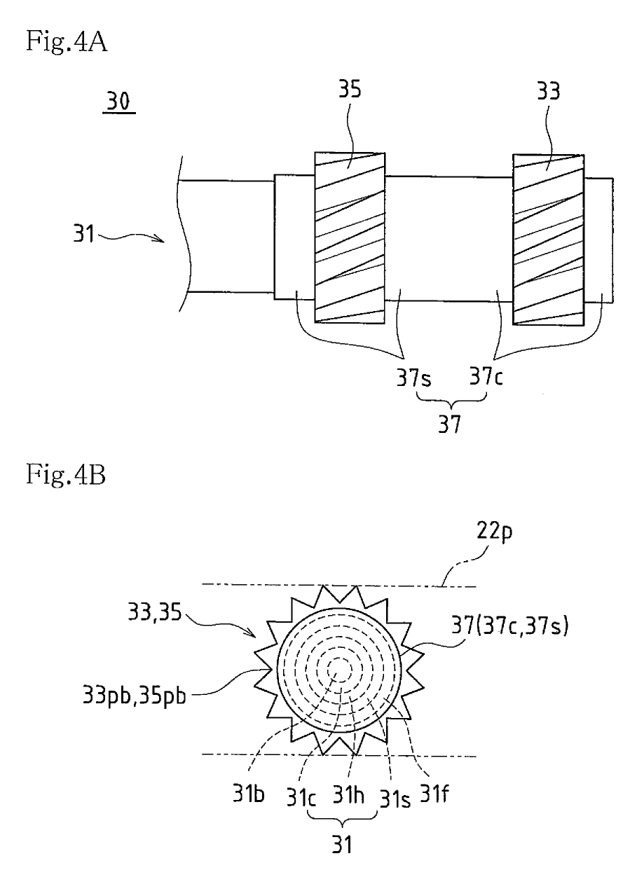

FIGS. 4A, 4B are explanatory diagrams illustrating the overall structure obtained when the resin encapsulation portion is formed by encapsulating the shielding wire coupler and conductor wire coupler connected to the cable of the cable component according to Embodiment 1 of the present invention, where FIG. 4A is a plan elevation and FIG. 4B is an end elevation of FIG. 4A viewed in the direction of the distal end.

Step S3:

A resin encapsulation portion 37 (encapsulation portion 37c facing the end face in the length direction of the cable 31, or simply encapsulation portion 37 when the position is not of particular importance) is formed, which encapsulates the end face of the conductor wire coupler 33 in the length direction of the conductor wire 31c in resin (resin encapsulation portion formation step).

Based on this configuration, the cable component 30, which has a conductor wire coupler 33 connected to a cable-type composite printed wiring board, can be manufactured easily and with high productivity.

Moreover, a resin encapsulation portion 37 (encapsulation portion 37s facing the end face in the length direction of the cable 31, or simply encapsulation portion 37 when the position is not of particular importance) is formed, which encapsulates the end face of the shielding wire coupler 35 in the length direction of the shielding wire 31c in resin (resin encapsulation portion formation step).

Based on this configuration, the shielding wire coupler 35, which is connected to a cable-type composite printed wiring board, can be positioned with accuracy and cable component 30, which possesses an effective shielding capability, can be manufactured easily and with high productivity.

The formation of the resin encapsulation portion 37c encapsulating the end face of the conductor wire coupler 33 in the length direction of the conductor wire 31c in resin permits secure encapsulation of the portion in which the conductor wire coupler 33 is joined to the conductor wire 31c and permits improvements in the mechanical strength and reliability of the conductor wire coupler 33.

Due to the fact that the encapsulation portion 37c is of true circular shape, the shape of the resin encapsulation portion 37 relative to the first wiring board 10 and second wiring boards 20 can be maintained constant even if the cable component 30 rotates, and the coupling of the cable component 30 to the first wiring board 10 and second wiring boards 20 can be accomplished in an easy and reliable manner.

Since the outer periphery of the encapsulation portion 37c is disposed closer to the cable 31c than to the bottom portion 33pb of the conductor wire projections 33p, when the encapsulation portion 37c is formed, the encapsulant resin can be prevented from filling the gaps between the conductor wire projections 33p and the cable component 30 can be formed in high yields.

The formation of the resin encapsulation portion 37s encapsulating the end face of the shielding wire coupler 35 in the length direction of the conductor wire 31c in resin permits secure encapsulation of the portion where the shielding wire coupler 35 is joined to the conductor wire 31c and permits improvements in the mechanical strength and reliability of the shielding wire coupler 35.

Due to the fact that the encapsulation portion 37s is of true circular shape, the shape of the resin encapsulation portion 37 relative to the first wiring board 10 and second wiring boards 20 can be maintained constant even if the cable component 30 rotates, and the coupling of the cable component 30 to the first wiring board 10 and second wiring boards 20 can be accomplished in an easy and reliable manner.

Since the outer periphery of the encapsulation portion 37s is disposed closer to the shielding wire 31s than to the bottom portion 35pb of the shielding wire projections 35p, when the encapsulation portion 37s is formed, the encapsulant resin can be prevented from filling the gaps between the conductor wire projections 35p and the cable component 30 can be formed in high yields.

As described above, the cable component 30 according to the present embodiment is suitable for use in a cable-type composite printed wiring board including a first wiring board 10 having a first insulating substrate 11 and a first conductor layer pattern 12p; second wiring boards 20, which have a second insulating substrate 21 and a second conductor layer pattern 22p and are laminated onto the first wiring board 10; and a cable component 30, which is juxtaposed with the first wiring board 10 and connected to the second conductor layer pattern 22p. Moreover, the cable component 30 according to the present embodiment includes a cable 31 having a conductor wire 31c and a sheath portion 31h insulating the conductor wire 31c; and a planetary gear-shaped conductor wire coupler 33 which is connected to the conductor wire 31c and has conductor wire projections 33p which, by passing through the second insulating substrate 21, abut against the second conductor layer pattern 22p.

Moreover, in the cable component 30 according to the present embodiment, the cable 31 has a shielding wire 31s arranged on the outer periphery of the sheath portion 31h and an outer sheath portion 31f sheathing the shielding wire 31s; and a planetary gear-shaped shielding wire coupler 35 which is connected to the shielding wire 31s and has shielding wire projections 35p which, by passing through the second insulating substrate 21, abut against the second conductor layer pattern 22p.

As described above, the cable component fabrication method used for the fabrication of the cable component 30 according to the present embodiment is a fabrication process used for the fabrication of the cable component 30 suitable for use in a cable-type composite printed wiring board including a first wiring board 10 having a first insulating substrate 11 and a first conductor layer pattern 12p; second wiring boards 20, which have a second insulating substrate 21 and a second conductor layer pattern 22p and are laminated onto the first wiring board 10; and a cable component 30, which is juxtaposed with the first wiring board 10 and connected to the second conductor layer pattern 22p.

Moreover, the cable component fabrication process used for the fabrication of the cable component 30 according to the present embodiment includes the steps of: cable preparation, which involves preparing a cable 31 having a conductor wire 31c and a sheath portion 31h insulating the conductor wire 31c and exposing the cable 31c; coupler connection, which involves preparing a planetary gear-shaped conductor wire coupler 33 which is connected to the conductor wire 31c and has conductor wire projections 33p which, by passing through the second insulating substrate 21, abut against the second conductor layer pattern 22p, and connecting it to the conductor wire 31c; and resin encapsulation portion formation, which involves forming an encapsulation portion 37 encapsulating the end face of the conductor wire coupler 33 in the length direction of the conductor wire 31c in resin.

Moreover, in the cable component fabrication process used for the fabrication of the cable component 30 according to the present embodiment, the cable 31 has a shielding wire 31s arranged on the outer periphery of the sheath portion 31h and an outer sheath portion 31f sheathing the shielding wire 31s; and the cable component 30 includes a planetary gear-shaped shielding wire coupler 35 which is connected to the shielding wire 31s and has shielding wire projections 35p which, by passing through the second insulating substrate 21, abut against the second conductor layer pattern 22p, and, in the cable preparation step, the shielding wire 31s is exposed; in the coupler connection step, the shielding wire coupler 35 is prepared and connected to the shielding wire 31s; and in the resin encapsulation portion formation step, a resin encapsulation portion 37 is formed which encapsulates the end face of the shielding wire coupler 35 in the length direction of the shielding wire 31s in resin.

Here, FIG. 5A through FIG. 11B will be used to explain the conductor wire coupler 33 (shielding wire coupler 35) of the cable component 30 used in Embodiment 1 of the present invention.

FIG. 5A, FIG. 5B, FIG. 5C, and FIG. 5D are explanatory diagrams used to explain coupling to the second conductor layer pattern when the conductor wire coupler of the cable component according to Embodiment 1 of the present invention has four conductor wire projections, where FIG. 5A is a side elevation viewed from the side in the direction of substrate lamination, FIG. 5B is an end elevation viewed in the direction of arrow B in FIG. 5A, FIG. 5C is a side elevation viewed from the side in the direction of substrate lamination, and FIG. 5D is an end elevation viewed in the direction of arrow D in FIG. 5C.

Since the basic structure of the conductor wire coupler 33 illustrated in FIG. 5A through FIG. 5D is the same as that of the conductor wire coupler 33 illustrated in FIG. 3A through FIG. 3D, explanations will be made primarily regarding the differences.

The planetary gear-shaped conductor wire coupler 33 has four (an even number) of conductor wire projections 33p in the so-called “plus” shape. The conductor wire projections 33p, which are triangular in cross-section, are formed at the distal ends of the plus shape. Moreover, its thickness Tg in the length direction of the conductor wire 31c is set appropriately so as to minimize connection resistance between the conductor wire coupler 33 and the second conductor layer pattern 22p.

FIG. 5A and FIG. 5B illustrate an unstable arrangement, where two of the four conductor wire projections 33p are positioned in alignment with the direction of the Y-axis (substrate lamination direction Dst), abutting against the second conductor layer pattern 22p. In the state depicted in FIG. 5A and FIG. 5B, the arrangement of the conductor wire coupler 33 (conductor wire projections 33p) is unstable. In order to obtain a stable state when laminating the second wiring boards 20 (second insulating substrate 21, second conductor layer 22), it can be turned by θ degrees to obtain the state depicted in FIG. 5C and FIG. 5D

In the state depicted in FIG. 5C and FIG. 5D, all four of the conductor wire projections 33p abut against the second conductor layer pattern 22p and therefore, stability is increased. However, the angle of rotation, i.e. 45 degrees, is considerable, and the variation in thickness in the substrate lamination direction Dst (height of conductor wire coupler 33) is high.

In the state depicted in FIG. 5C and FIG. 5D, the angle of intersectional between one of the planes of the conductor wire projections 33p (one plane out of the two planes that the conductor wire projections 33p form) and the second conductor layer pattern 22p is an obtuse angle overhanging the second conductor layer pattern 22p, as a result of which the area of abutment is substantially reduced and the connection resistance may be increased. On the other hand, the angle of intersection α2 of the other plane of the conductor wire projections 33p and the second conductor layer pattern 22p is an acute angle, such that abutment can be effected in the normal way and the connection resistance will be reduced.

Since the number of the conductor wire projections 33p is set to en even number, when the second wiring boards 20 (second conductor layer pattern 22p) are disposed symmetrically on both sides of the first wiring board 10, the conductor wire projections 33p are brought into symmetrical abutment with the second wiring boards 20 (second conductor layer pattern 22p) on both sides, thereby making it possible to achieve the same connection properties between the second conductor layer pattern 22p on both sides and the first wiring board 10.

As for the basic structure of the shielding wire coupler 35, it can be the same as that of the shielding wire coupler 35 illustrated in FIG. 3A through FIG. 3C and, desirably, has the same configuration as the conductor wire coupler 33 illustrated in FIG. 5A through FIG. 5D. In other words, it is desirable for the planetary gear-shaped shielding wire coupler 35 (shielding wire projections 35p) to have the same configuration as the conductor wire coupler 33 (conductor wire projections 33p).

For instance, the number of the shielding wire projections 35p is set to an even number. For this reason, when the second wiring boards 20 (second conductor layer patterns 22p) are disposed symmetrically on both sides of the first wiring board 10, the shielding wire projections 35p are brought into symmetrical abutment with the second wiring boards 20 (second conductor layer patterns 22p) on both sides, thereby making it possible to achieve the same connection properties between the second conductor layer pattern 22p on both sides and the first wiring board 10.

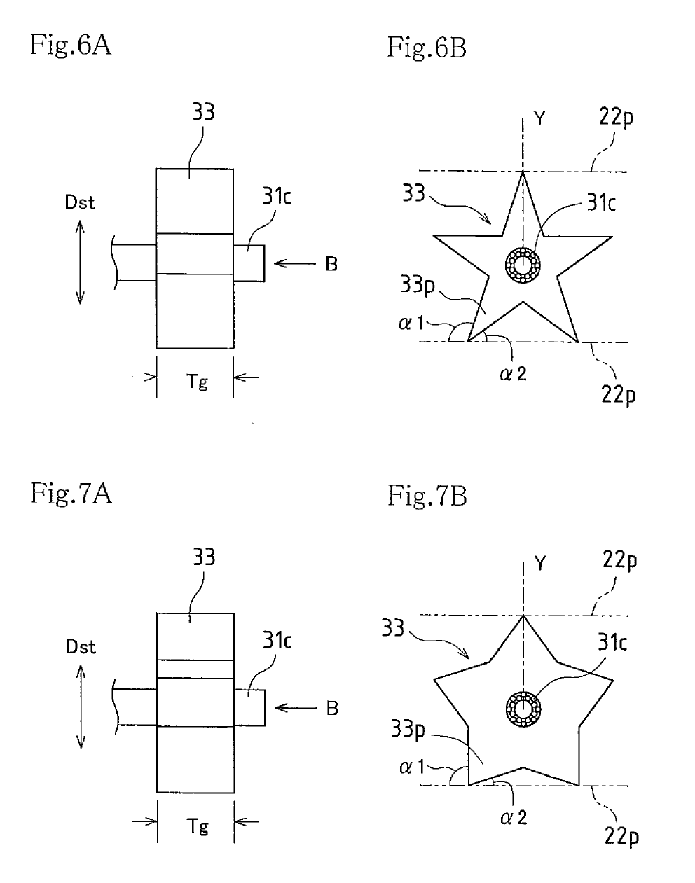

FIG. 6A and FIG. 6B are explanatory diagrams used to explain coupling to the second conductor layer pattern when the conductor wire coupler of the cable component according to Embodiment 1 of the present invention has five conductor wire projections, where FIG. 6A is a side elevation viewed from the side in the direction of substrate lamination and FIG. 6B is an end elevation viewed in the direction of arrow B in FIG. 6A.

Since the basic structure of the conductor wire coupler 33 illustrated in FIG. 6A and FIG. 6B is the same as that of the conductor wire coupler 33 illustrated in FIG. 5A through FIG. 5D, explanations will be made primarily regarding the differences.

The planetary gear-shaped conductor wire coupler 33 has five (an odd number) of conductor wire projections 33p in the so-called “star” shape. The conductor wire projections 33p, which are triangular in cross-section, are formed at the distal ends of the star shape.

Since the number of the conductor wire projections 33p is an odd number, their is asymmetry with respect to the second conductor layer pattern 22p disposed on both sides of the substrate lamination direction Dst. Namely, e.g. in FIG. 6B, the conductor wire projections 33p are in a stable state with two projections bearing against the second conductor layer pattern 22p disposed at the bottom. In FIG. 6B, there is an unstable state with only one projection bearing against the second conductor layer pattern 22p disposed at the top and, since the number is small, the connection resistance is asymmetrical and increases.

As for the angles of intersection α1 and α2, the situation is the same as in case of FIG. 5C and FIG. 5D.

FIG. 7A and FIG. 7B are explanatory diagrams used to explain coupling to the second conductor layer pattern obtained when the conductor wire coupler of the cable component according to Embodiment 1 of the present invention has five conductor wire projections, where FIG. 7A is a side elevation viewed from the side in the direction of substrate lamination and FIG. 7B is an end elevation viewed in the direction of arrow B in FIG. 7A.

Since the basic structure of the conductor wire coupler 33 illustrated in FIG. 7A and FIG. 7B is the same as that of the conductor wire coupler 33 illustrated in FIG. 6A and FIG. 6B, explanations will focus primarily on the differences. The gaps of the bottom portions 33pb are increased in comparison with the conductor wire projections 33p in FIG. 6A and FIG. 6B such that the bottom portions of the triangular conductor wire projections 33p are widened in comparison with FIG. 6A and FIG. 6B.

By increasing the gaps of the bottom portions 33pb, the angle of intersectional is set to 90 degrees. For this reason, the overhang can be eliminated.

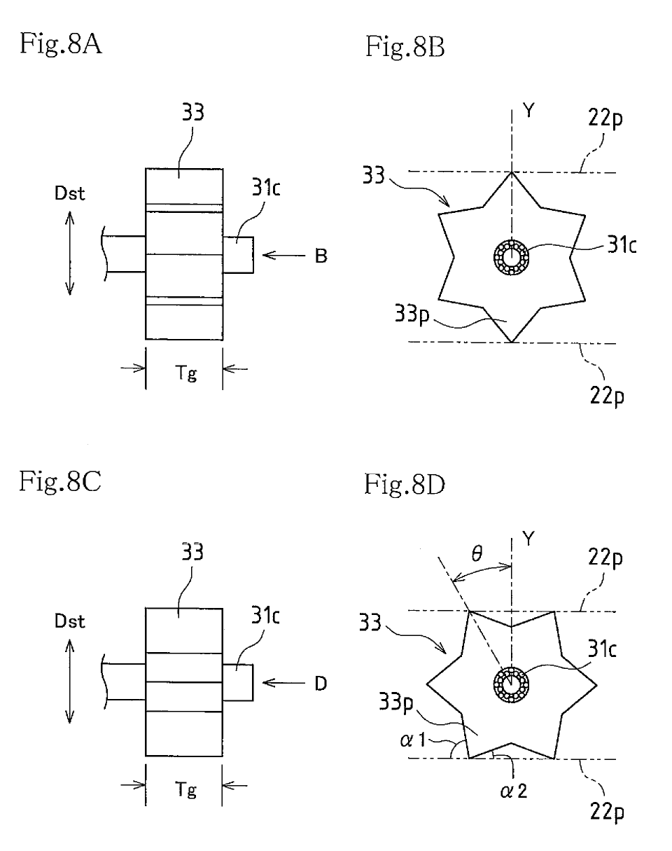

FIG. 8A, FIG. 8B, FIG. 8C, and FIG. 8D are explanatory diagrams used to explain coupling to the second conductor layer pattern when the conductor wire coupler of the cable component according to Embodiment 1 of the present invention has 6 conductor wire projections, where FIG. 8A is a side elevation viewed from the side in the direction of substrate lamination, FIG. 8B is an end elevation viewed in the direction of arrow B in FIG. 8A, FIG. 8C is a side elevation viewed from the side in the direction of substrate lamination, and FIG. 8D is an end elevation viewed in the direction of arrow D in FIG. 8C.

Since the basic structure of the conductor wire coupler 33 illustrated in FIG. 8A through FIG. 5D is the same as that of the conductor wire coupler 33 illustrated in FIG. 5A through FIG. 5D, explanations will be made primarily regarding the differences.

While four conductor wire projections 33p were used in FIG. 5A through FIG. 5D, here, the planetary gear-shaped conductor wire coupler 33 is different from the case of FIG. 5A through FIG. 5D in that it is configured to have 6 (an even number) of conductor wire projections 33p.

FIG. 8A and FIG. 8B illustrate an unstable arrangement, where two of the six conductor wire projections 33p are positioned in alignment with the direction of the Y-axis (substrate lamination direction Dst), abutting against the second conductor layer pattern 22p. In the state depicted in FIG. 8A and FIG. 8B, the arrangement of the conductor wire coupler 33 (conductor wire projections 33p) is unstable. In order to obtain a stable state when laminating the second wiring boards 20 (second insulating substrate 21, second conductor layer 22), it can be turned by θ degrees to obtain the state depicted in FIG. 8C and FIG. 8D.

In the state depicted in FIG. 5C and FIG. 8D, four of the conductor wire projections 33p abut against the second conductor layer pattern 22p and therefore, stability is increased. Moreover, the angle of rotation is 30 degrees and can be made relatively smaller than in case of FIG. 5C and FIG. 5D, thereby making it possible to reduce changes in thickness (height of the conductor wire coupler 33) in the substrate lamination direction Dst in comparison with FIG. 5C and FIG. 5D.

Since the number of the conductor wire projections 33p is set to 6, the triangular shape of the conductor wire projections 33p is appropriate, and the angles of intersection α1, α2 of the plane defined by the conductor wire projections 33p and the plane of the second conductor layer pattern 22p can be easily set to 90 degrees or less. For this reason, the overhang is eliminated, and the conductor wire projections 33p are placed in a position directly opposite the second conductor layer pattern 22p.

In other words, the conductor wire projections 33p are desirably disposed such that the angles of intersection α1, α2 of the plane defined by the conductor wire projections 33p and the plane of the second conductor layer pattern 22p are set to 90 degrees or less.

This configuration permits prevention of the bending, etc. of the conductor wire projections 33p, or leakage of pressure on the conductor wire projections 33p when the second wiring boards 20 (second insulating substrate 21, second conductor layer 22) are laminated onto the first wiring board 10 and conductor wire coupler 33, which makes it possible to bring the conductor wire coupler 33 into secure abutment with the second conductor layer pattern 22p.

Moreover, as described above, the number of the conductor wire projections 33p is preferably set to 6 or more.

This configuration permits stabilization of the positional relationship of the conductor wire projections 33 p in respect to the second conductor layer pattern 22p using small angles of rotation θ and makes it possible to easily bring the conductor wire projections 33p into secure abutment with the second conductor layer pattern 22p.

The shielding wire coupler 35 desirably has the same configuration as the conductor wire coupler 33 illustrated in FIG. 8A through FIG. 8D.

In other words, the shielding wire projections 35p are desirably disposed such that the angle of intersection of the plane defined by the shielding wire projections 35p and the plane of the second conductor layer pattern 22p is set to 90 degrees or less.

This configuration permits prevention of the bending, etc. of the shielding wire projections 35p, or leakage of pressure on the shielding wire projections 35p when the second wiring boards 20 (second insulating substrate 21, second conductor layer 22) are laminated onto the first wiring board 10 and shielding wire coupler 35, which makes it possible to bring the shielding wire coupler 35 into secure abutment with the second conductor layer pattern 22p.

Moreover, the number of the shielding wire projections 35p is preferably set to 6 or more.

This configuration permits stabilization of the positional relationship of the shielding wire projections 35p in respect to the second conductor layer pattern 22p using small angles of rotation θ and makes it possible to easily bring the shielding wire projections 35p into secure abutment with the second conductor layer pattern 22p.

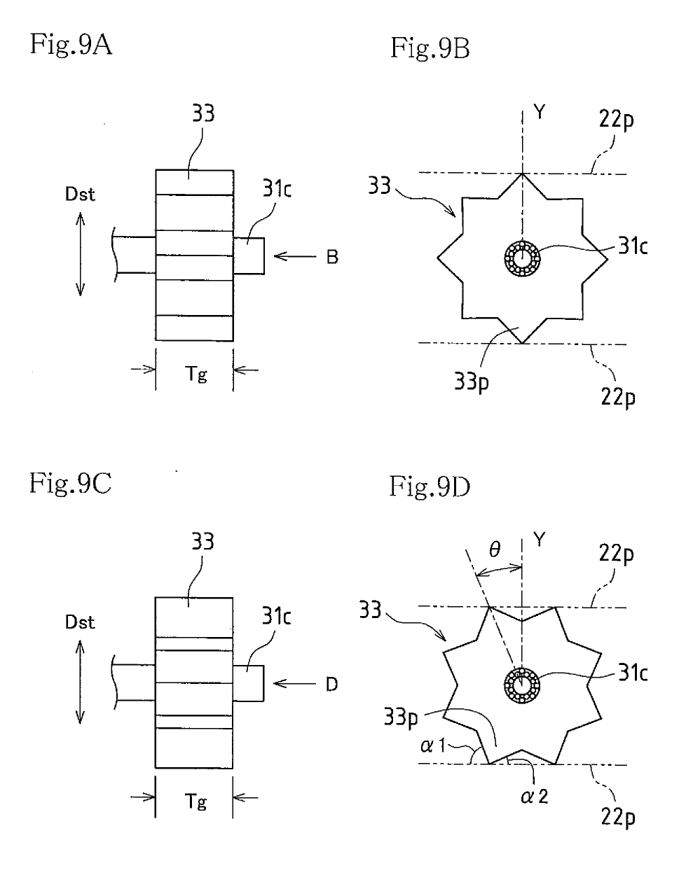

FIG. 9A, FIG. 9B, FIG. 9C, and FIG. 9D are explanatory diagrams used to explain coupling to the second conductor layer pattern when the conductor wire coupler of the cable component according to Embodiment 1 of the present invention has 8 conductor wire projections, where FIG. 9A is a side elevation viewed from the side in the direction of substrate lamination, FIG. 9B is an end elevation viewed in the direction of arrow B in FIG. 9A, FIG. 9C is a side elevation viewed from the side in the direction of substrate lamination, and FIG. 9D is an end elevation viewed in the direction of arrow D in FIG. 9C.

Since the basic structure of the conductor wire coupler 33 illustrated in FIG. 9A through FIG. 9D is the same as that of the conductor wire coupler 33 illustrated in FIG. 8A through FIG. 8D, explanations will be made primarily regarding the differences.

While six conductor wire projections 33p were used in FIG. 8A through FIG. 5D, here, the planetary gear-shaped conductor wire coupler 33 is different from the case of FIG. 5A through FIG. 8D in that it is configured to have 8 (an even number) of conductor wire projections 33p. By setting the number of the conductor wire projections 33p to eight, the angle of rotation θ is set to 22.5 degrees and can be made relatively smaller than in FIG. 8A through FIG. 8D, thereby enabling a reduction in thickness fluctuations (height of the conductor wire coupler 33) in the substrate lamination direction Dst in comparison with FIG. 8A through FIG. 8D.

Moreover, the angles of intersection α1, α2 can be configured in a more symmetrical way in comparison with FIG. 8A through FIG. 8D, thereby improving the degree to which the conductor wire projections 33p are directly opposed to the second conductor layer pattern 22p and ensuring secure abutment.

The shielding wire coupler 35 desirably has the same configuration as the conductor wire coupler 33 illustrated in FIG. 9A through FIG. 9D.

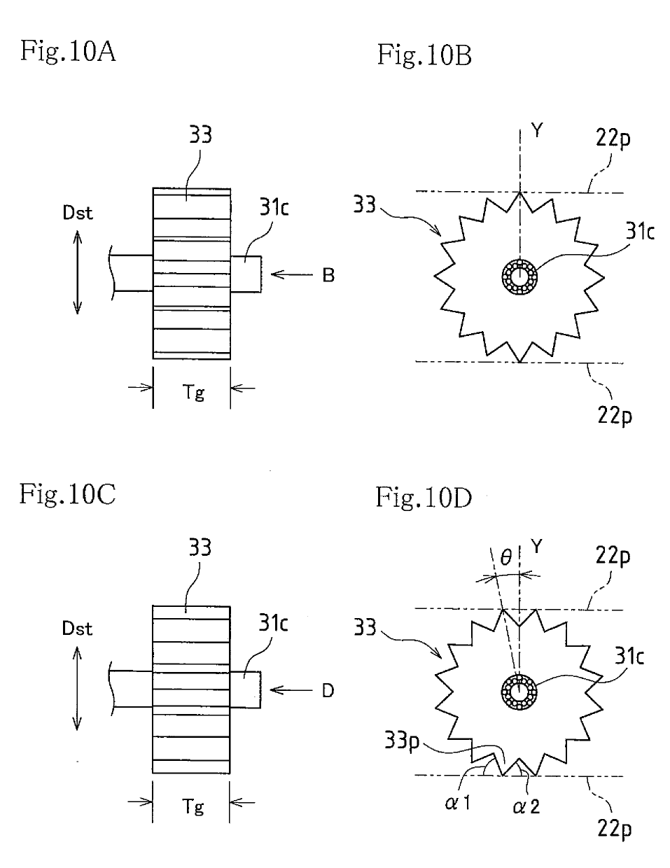

FIG. 10A, FIG. 10B, FIG. 10C, and FIG. 10D are explanatory diagrams used to explain coupling to the second conductor layer pattern when the conductor wire coupler of the cable component according to Embodiment 1 of the present invention has 16 conductor wire projections, where FIG. 10A is a side elevation viewed from the side in the direction of substrate lamination, FIG. 10B is an end elevation viewed in the direction of arrow B in FIG. 10A, FIG. 10C is a side elevation viewed from the side in the direction of substrate lamination, and FIG. 10D is an end elevation viewed in the direction of arrow D in FIG. 10C.

Since the basic structure of the conductor wire coupler 33 illustrated in FIG. 10A through FIG. 10D is the same as that of the conductor wire coupler 33 illustrated in FIG. 9A through FIG. 9D, explanations will be made primarily regarding the differences.

While there were eight conductor wire projections 33p used in FIG. 9A through FIG. 9D, here, the planetary gear-shaped conductor wire coupler 33 is different from the case of FIG. 9A through FIG. 9D in that it is configured to have 16 (an even number) of conductor wire projections 33p.

By setting the number of the conductor wire projections 33p to sixteen, the angle of rotation θ is set to 11.25 degrees and can be made even smaller than in FIG. 9A through FIG. 9D, thereby enabling a further reduction in thickness fluctuations (height of the conductor wire coupler 33) in the substrate lamination direction Dst in comparison with FIG. 9A through FIG. 9D.

Moreover, the angles of intersection α1, α2 can be configured in a more symmetrical way in comparison with FIG. 9A through FIG. 9D, thereby improving the degree to which the conductor wire projections 33p are directly opposed to the second conductor layer pattern 22p and ensuring secure abutment.

In other words, increasing the number of planetary gear-shaped projections, i.e. the number of the conductor wire projections 33p, makes it possible to reduce the angle of rotation θ required when mounting the cable component 30 and improve the degree to which they are directly opposed to the second conductor layer pattern 22p, thereby improving the operability of the connection of the second conductor layer pattern 22p to the cable component 30 and minimizing the connection resistance between the conductor wire coupler 33 and second conductor layer pattern 22p.

Moreover, increasing the number of conductor wire projections 33p makes it possible to widen the range of adjustment of the height of the conductor wire projections 33p (the height of the gap between the apices 33pt and bottom portions 33pb), thereby permitting the conductor wire projections 33p to be configured to have a shape corresponding to the thickness of the second conductor layer 22 (second conductor layer pattern 22p).

The shielding wire coupler 35 desirably has the same configuration as the conductor wire coupler 33 illustrated in FIG. 10A through FIG. 10D.

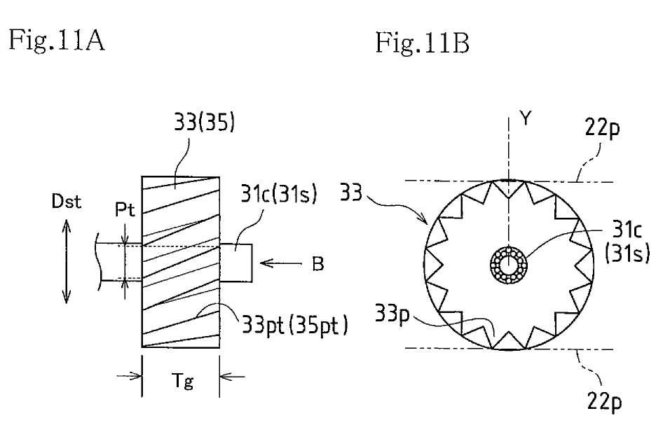

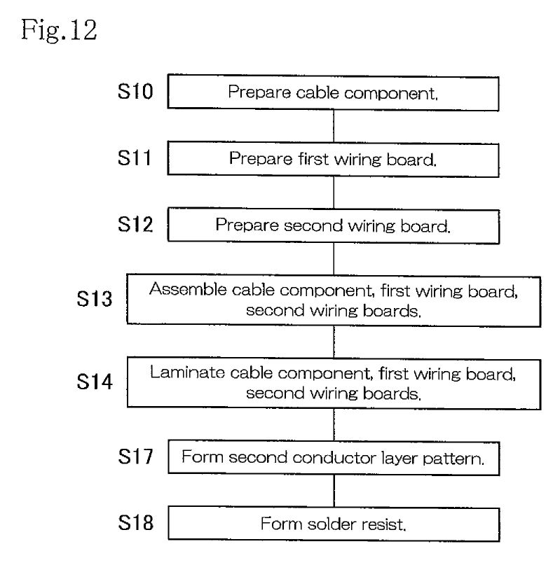

FIG. 11A and FIG. 11B are explanatory diagrams used to explain coupling to the second conductor layer pattern when the conductor wire projections of the conductor wire coupler of the cable component according to Embodiment 1 of the present invention have a helical gear-like shape, where FIG. 11A is a side elevation viewed from the side in the direction of substrate lamination and FIG. 11B is an end elevation viewed in the direction of arrow B in FIG. 11A.

Since the basic structure of the conductor wire coupler 33 illustrated in FIG. 11A and FIG. 11B is the same as that of the conductor wire coupler 33 illustrated in FIG. 10A through FIG. 10D, explanations will be made primarily regarding the differences.

The planetary gear-like shape of the conductor wire coupler 33 is preferably a helical gear-like shape with obliquely formed conductor wire projections 33p.

This configuration makes it possible to minimize the stress whereby the conductor wire coupler 33 tends to rotate needlessly in the direction of stabilization when the second wiring boards 20 (second insulating substrate 21, second conductor layer 22) are laminated onto the first wiring board 10 and conductor wire coupler 33, which makes it possible to easily and securely position the conductor wire coupler 33 (conductor wire projections 33p).

The obliqueness of the helical gear-shaped apices 33pt of the conductor wire coupler 33 with respect to the thickness Tg of the conductor wire coupler 33 in the length direction of the conductor wire 31c is preferably greater than the inter-apex pitch Pt.

This configuration makes it possible to impart a cylindrical shape to the surface (external contact surface) defined by the apices 33pt of the conductor wire coupler 33, as a result of which the conductor wire projections 33p can be brought into secure abutment with the second conductor layer pattern 22p at any position in the direction of the thickness Tg of the conductor wire coupler 33 and the conductor wire coupler 33 (conductor wire projections 33p) can be easily and securely positioned.

The shielding wire coupler 35 desirably has the same configuration as the conductor wire coupler 33 illustrated in FIG. 11A and FIG. 11B.

Namely, the planetary gear-like shape of the shielding wire coupler 35 is preferably a helical gear-like shape with obliquely formed shielding wire projections 35p (while the drawing is omitted, the resultant shape has a shielding wire 35s instead of the conductor wire 31c).

This configuration makes it possible to minimize the stress whereby the shielding wire coupler 35 tends to rotate needlessly in the direction of stabilization when the second wiring boards 20 (second insulating substrate 21, second conductor layer 22) are laminated onto the first wiring board 10 and shielding wire coupler 35, which makes it possible to easily and securely position the shielding wire coupler 35 (shielding wire projections 35p).

Moreover, the obliqueness of the helical gear-shaped apices 35pt of the shielding wire coupler 35 with respect to the thickness Tg of the shielding wire coupler 35 in the length direction of the conductor wire 31c is preferably greater than the inter-apex pitch Pt (while the drawing is omitted, the resultant shape has a shielding wire 31s instead of the conductor wire 31c).

This configuration makes it possible to impart a cylindrical shape to the surface (external contact surface) defined by the apices 35pt of the shielding wire coupler 35, as a result of which the shielding wire projections 35p can be brought into secure abutment with the second conductor layer pattern 22p at any position in the direction of the thickness Tg of the shielding wire coupler 35 and the shielding wire coupler 35 (shielding wire projections 35p) can be easily and securely positioned.

As described above, the cable component 30 according to the present embodiment, which is a cable component 30 suitable for use in a cable-type composite printed wiring board including a first wiring board 10 having a first insulating substrate 11 and a first conductor layer pattern 12p; second wiring boards 20, which have a second insulating substrate 21 and a second conductor layer pattern 22p and are laminated onto the first wiring board 10; and a cable component 30, which is juxtaposed with the first wiring board 10 and connected to the second conductor layer pattern 22p, has a cable 31 having a conductor wire 31c and a sheath portion 31h insulating the conductor wire 31c, and a planetary gear-shaped conductor wire coupler 33 which is connected to the conductor wire 31c and has conductor wire projections 33p which, by passing through the second insulating substrate 21, abut against the second conductor layer pattern 22p.

For this reason, the conductor wire 31c can be easily and accurately connected to the second conductor layer pattern 22p through the conductor wire coupler 33, which makes it possible to obtain a cable component 30 permitting easy and accurate connection of the conductor wire 31c to the second wiring boards 20 (second conductor layer pattern 22p) of the cable-type composite printed wiring board.

In other words, due to the fact that the conductor wire 31c (cable component 30) and the second conductor layer pattern 22p can be easily and firmly connected, a cable-type composite printed wiring board can be obtained that permits a reduction in size, a reduction in thickness, and allows for free spatial configuration, makes it possible to dependably effect signal transmission and provides high reliability of connection between the cable component 30 and the second conductor layer pattern 22p.

Moreover, in the cable component 30 according to the present embodiment, the cable 31 includes: a shielding wire 31s arranged on the outer periphery of the sheath portion 31h and an outer sheath portion 31f sheathing the shielding wire 31s; and a planetary gear-shaped shielding wire coupler 35 connected to the shielding wire 31s and having shielding wire projections 35p which, by passing through the second insulating substrate 21, abut against the second conductor layer pattern 22p.

For this reason, the shielding wire 31s can be easily and accurately connected to the second conductor layer pattern 22p through the shielding wire coupler 35, which makes it possible to obtain a cable component 30 permitting easy and accurate connection of the shielding wire 31s to the second wiring boards 20 (second conductor layer pattern 22p) of the cable-type composite printed wiring board.

Namely, due to the fact that the shielding wire 31s can be easily and securely connected to the second conductor layer pattern 22p, it becomes possible to obtain a cable-type composite printed wiring board including a cable component 30 in which the reliability of the connection between the cable component 30 (shielding wire 31s) and the second conductor layer pattern 22p is improved, the shielding properties are enhanced, and which has superior high-frequency characteristics.

Moreover, as described above, the cable component fabrication process according to the present embodiment, which is a cable component fabrication process used to fabricate a cable component 30 suitable for use in a cable-type composite printed wiring board including a first wiring board 10 having a first insulating substrate 11 and a first conductor layer pattern 12p; second wiring boards 20, which have a second insulating substrate 21 and a second conductor layer pattern 22p and are laminated onto the first wiring board 10; and a cable component 30, which is juxtaposed with the first wiring board 10 and connected to the second conductor layer pattern 22p, includes the steps of: cable preparation, which involves preparing a cable 31 having a conductor wire 31c and a sheath portion 31h insulating the conductor wire 31c and exposing the cable 31c; coupler connection, which involves preparing a planetary gear-shaped conductor wire coupler 33 connected to the conductor wire 31c and having conductor wire projections 33p which, by passing through the second insulating substrate 21, abut against the second conductor layer pattern 22p, and connecting it to the conductor wire 31c; and resin encapsulation portion formation, which involves forming an encapsulation portion 37 encapsulating the end face of the conductor wire coupler 33 in the length direction of the conductor wire 31c in resin.

For this reason, the cable component 30, which permits accurate positioning of the conductor wire coupler 33 connected to the cable-type composite printed wiring board, can be manufactured easily and with high productivity.

Moreover, in the cable component fabrication process according to the present embodiment, the cable 31 has a shielding wire 31s arranged on the outer periphery of the sheath portion 31h and an outer sheath portion 31f sheathing the shielding wire 31s; and the cable component 30 includes a planetary gear-shaped shielding wire coupler 35 connected to the shielding wire 31s and having a shielding wire projections 35p which, by passing through the second insulating substrate 21, abuts the second conductor layer pattern 22p, and, in the cable preparation step, the shielding wire 31s is exposed; in the coupler connection step, the shielding wire coupler 35 is prepared and connected to the shielding wire 31s; and in the resin encapsulation portion formation step, a resin encapsulation portion 37 is formed which encapsulates the end face of the shielding wire coupler 35 in the length direction of the shielding wire 31s in resin.

For this reason, the shielding wire coupler 35, which is connected to a cable-type composite printed wiring board, can be positioned with accuracy and cable component 30, which possesses an effective shielding capability, can be manufactured easily and with high productivity.

### Embodiment 2

The cable-type composite printed wiring board according to Embodiment 2 of the present invention (whose main portion, in a finished state, is illustrated in FIGS. 19A, 19B, and 19C) and a cable-type composite printed wiring board fabrication method used for the fabrication of the cable-type composite printed wiring board will be now explained with reference to FIG. 12 through FIG. 19C.

Since the cable-type composite printed wiring board according to the present embodiment is configured to use the cable component 30 explained in Embodiment 1, explanations will be in some cases omitted. Moreover, the characteristics of the cable component 30 explained in Embodiment 1 are applicable to the present embodiment. Moreover, explanations are provided using an example of a cable-type rigiflex printed wiring board, in which portions other than the cable component 30 of the cable-type composite printed wiring board are configured as rigid portions and which has a four-layer wiring structure (an inner layer substrate having wiring layers on both sides, and outer layer substrates disposed on the outside of the two sides of the inner layer substrate).

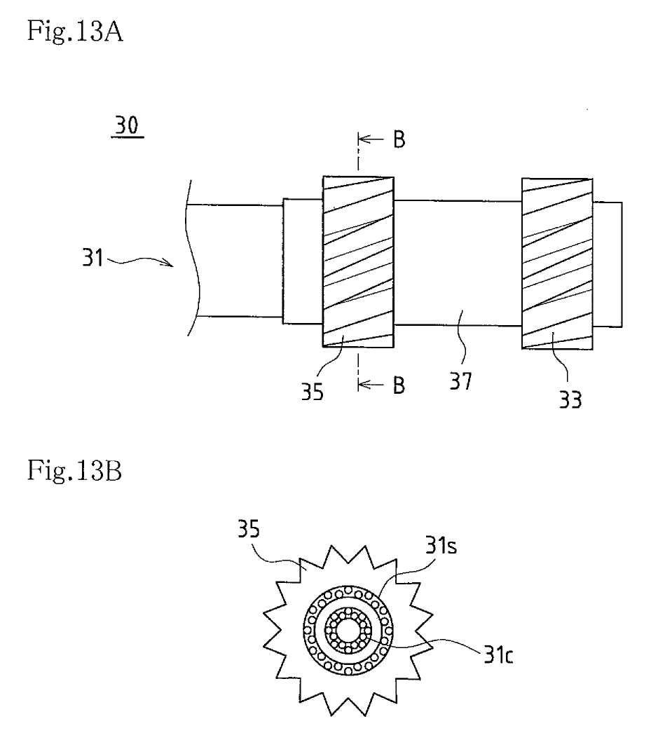

FIG. 12 is a flow chart schematically illustrating the flow of steps in the cable-type composite printed wiring board fabrication process used in Embodiment 2 of the present invention. Although each of the steps is explained below, they are to be considered in combination with FIG. 13A through FIG. 19C, which correspond to each step (S10 through S21).

The cable-type composite printed wiring board fabricated in accordance with the cable-type composite printed wiring board fabrication process of the present embodiment includes a first wiring board 10 having a first insulating substrate 11 and a first conductor layer pattern 12p, and second wiring boards 20, which are laminated onto the first wiring board 10 and have a second insulating substrate 21 and second conductor layer pattern 22p.

Moreover it includes a cable component 30 which is juxtaposed with the first wiring board 10 and includes a cable 31 having a conductor wire 31c and a sheath portion 31h insulating the conductor wire 31c, and a planetary gear-shaped conductor wire coupler 33 connected to the conductor wire 31c and having conductor wire projections 33p which, by passing through the second insulating substrate 20, abut against the second conductor layer pattern 22p (see FIGS. 19A through 19C).

It should be noted that the first wiring board 10 corresponds to the inner layer substrate (2 layers) in the four-layer structure and the second wiring boards 20 correspond to the outer layer substrates (2 layers).

As shown in Embodiment 1, in addition to the conductor wire 31c, the cable 31 includes a shielding wire 31s. In other words, in addition to a conductor wire coupler 33, the cable 31 includes a shielding wire coupler 35. Moreover, the shielding wire coupler 35 is a planetary gear-shaped coupler connected to the shielding wire 31s and having shielding wire projections 35p which, by passing through the second insulating substrate 21, abut against the second conductor layer pattern 22p.

Step 10:

FIGS. 13A, 13B are explanatory diagrams illustrating the cable component prepared in the cable preparation step of the cable-type composite printed wiring board fabrication process used in Embodiment 2 of the present invention, where FIG. 13A is a plan elevation and FIG. 13B is a side elevation, as viewed in the direction of the distal end of the cable. It should be noted that although the distal end of the cable 31 is illustrated in an exposed state, as shown in FIG. 4A and FIG. 4B, it may be encapsulated by the resin encapsulation portion 37.

The cable component 30 is prepared (cable preparation step). Namely, the cable component 30 which connects the conductor wire coupler 33 to the conductor wire 31c, is prepared. Moreover, in the cable preparation step, the shielding wire coupler 35 is connected to the shielding wire 31s in the same manner as the conductor wire coupler 33. The cable component 30 was explained in detail in Embodiment 1.

In the present embodiment, the cable component 30 used is the one illustrated in Embodiment 1 (FIG. 11A, FIG. 11B). Accordingly, the cable component 30 includes a planetary gear-shaped shielding wire coupler 33 having conductor wire projections 33p abutting against the second conductor layer pattern 22p and a planetary gear-shaped shielding wire coupler 35 having shielding wire projections 35p abutting against the second conductor layer pattern 22p, with the end faces of the conductor wire coupler 33 and shielding wire coupler 35 encapsulated in resin by the resin encapsulation portion 37, which is of a true circular form.

For this reason, the cable component 30 facilitates abutment against the second conductor layer pattern 22p in a stable state by means of rotation and enables highly reliable connection to the second conductor layer pattern 22p while maintaining a low connection resistance.

Step S11:

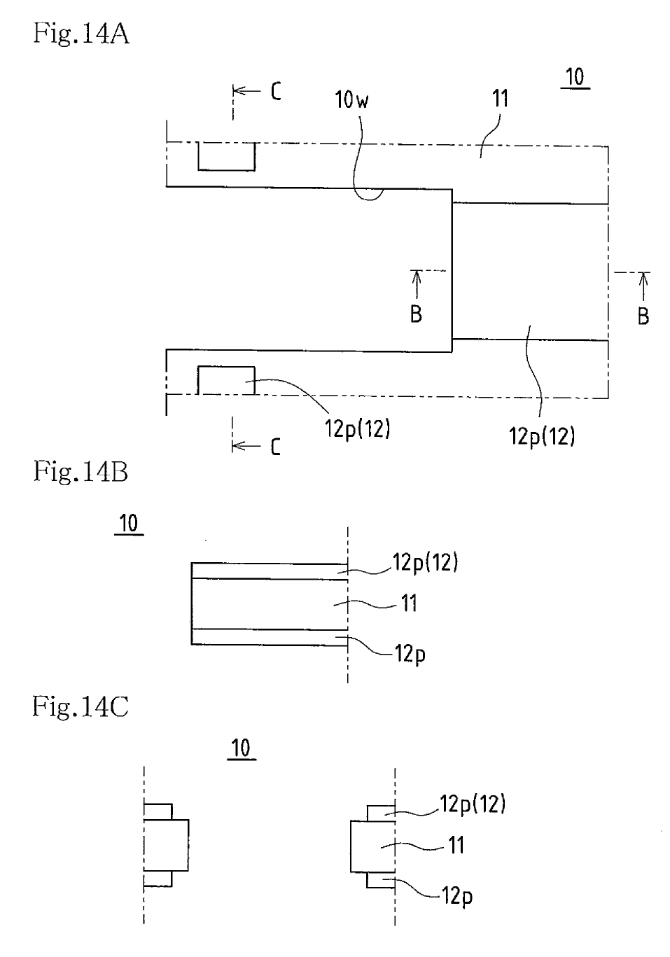

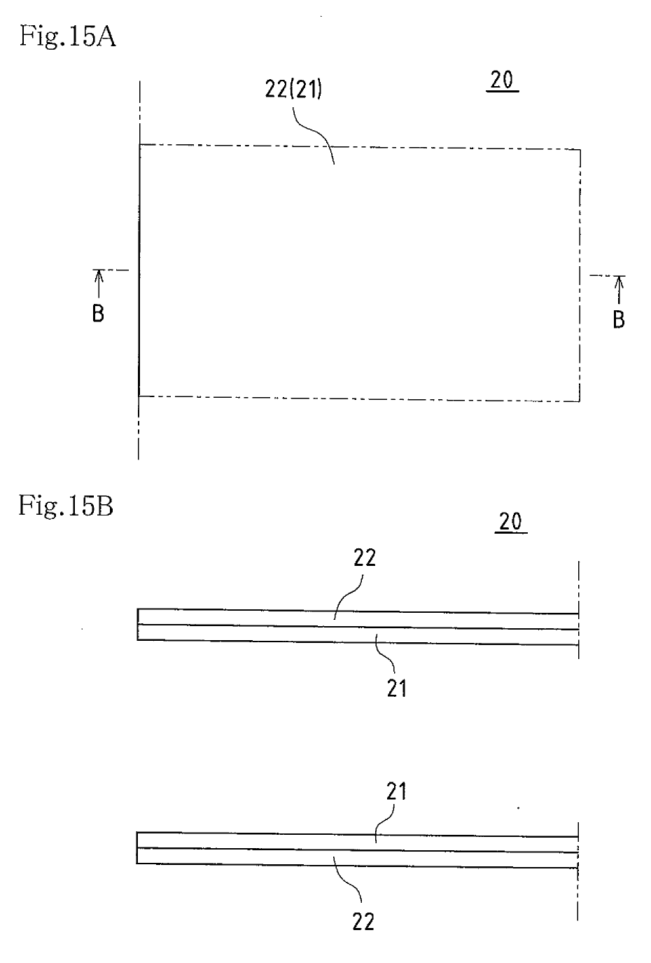

FIG. 14A, FIG. 14B, and FIG. 14C are explanatory diagrams illustrating the first wiring board prepared in the first wiring board preparation step of the cable-type composite printed wiring board fabrication process used in Embodiment 2 of the present invention, where FIG. 14A is a plan elevation, FIG. 14B is an end elevation illustrating the end face of a cross-section taken in the direction of arrow B-B in FIG. 14A, and FIG. 14C is an end elevation illustrating the end face of a cross-section taken in the direction of arrow C-C in FIG. 14A. It should be noted that hatching in the cross-section is omitted for ease of illustration (similarly to FIG. 15A through FIG. 19C).

The first wiring board 10 is prepared (first wiring board preparation step). Namely, the first wiring board 10, which serves as a double-sided wiring board, on which the first insulating substrate 11 and first conductor layer 12 are laminated, is prepared, and the first conductor layer pattern 12p, which has an appropriate pattern, is formed.

Moreover, a cable component window 10w, where cable component 30 is disposed (juxtaposed), is formed in the first wiring board 10 (first wiring board preparation step). The cable component window 10w is imparted a shape permitting juxtaposition of the conductor wire coupler 33 and shielding wire coupler 35.

The first wiring board 10 is constituted, for instance, by a double-sided rigid printed wiring board. A first conductor layer 12 is formed (laminated) on the first insulating substrate 11. Specifically, the first insulating substrate 11 is a glass fiber-reinforced epoxy resin board with a thickness of 0.5 mm, the first conductor layer 12 is made up of copper foil with a thickness of 18 μm, and a first conductor layer pattern 12p is formed by patterning the first conductor layer 12. The patterning operation can be carried out using well-known techniques.

The cable component window 10w can be made using, for instance, an NC router (numerical control router). By performing alignment with respect to the same position reference as the first conductor layer pattern 12p, a cable component window 10w can be formed that permits accurate alignment of the cable component 30 with the second conductor layer pattern 22p.

Step S12:

FIGS. 15A, 15B are explanatory diagrams illustrating the second wiring boards prepared in the second wiring board preparation step of the cable-type composite printed wiring board fabrication process used in Embodiment 2 of the present invention, where FIG. 15A is a plan elevation and FIG. 15B is an end elevation illustrating the end face of a cross-section taken in the direction of arrow B-B in FIG. 15A.

The second wiring boards 20 are prepared (second wiring board preparation step). Namely, the second wiring boards 20, on which the second conductor layer 22 used for forming the second conductor layer pattern 22p and the second insulating substrate 21 are laminated, are prepared (second wiring board preparation step).

The second wiring boards 20 are formed, for instance, by coating copper foil with a thickness of 18 μm, which serves as a second conductor layer, with an adhesive agent (an epoxy resin-based adhesive agent with a thickness of 100 μm) serving as the second insulating substrate 21.

The board is processed and molded to obtain a shape laminated onto the conductor wire coupler 33 and shielding wire coupler 35 of the cable component 30. A mold can be utilized for the molding operation.

Step S13:

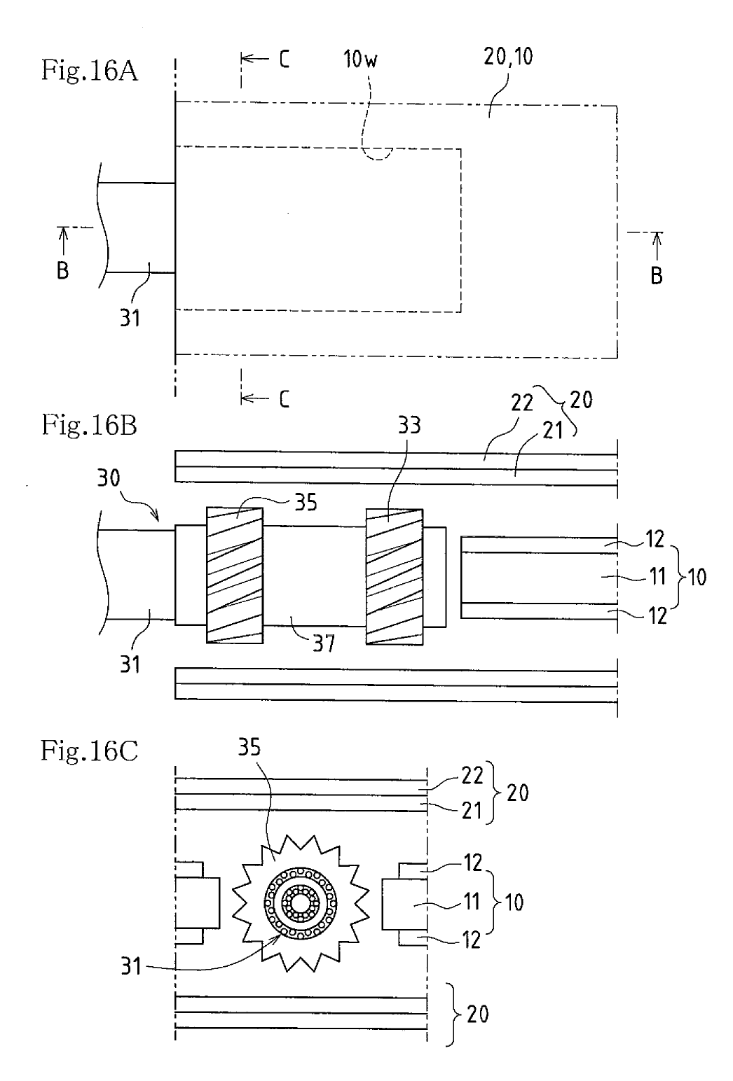

FIG. 16A, FIG. 16B, and FIG. 16C are explanatory diagrams illustrating a state obtained when the cable component, first wiring board, and second wiring boards are aligned in the cable component assembly step of the cable-type composite printed wiring board fabrication process used in Embodiment 2 of the present invention, where FIG. 16A is a plan elevation, FIG. 16B is a see-through side elevation showing the arrangement in a see-through manner in the direction of arrow B-B in FIG. 16A, and FIG. 16C is an end elevation illustrating the end face of a cross-section taken in the direction of arrow C-C in FIG. 16A.

The cable component 30, first wiring board 10, and second wiring boards 20 are assembled (cable component assembly step). In other words, the cable component 30 (conductor wire coupler 33, shielding wire coupler 35) is juxtaposed with (fitted to) the cable component window 10w and the second wiring boards 20 are aligned and stacked on the juxtaposed first wiring board 10 and cable component 30 (conductor wire coupler 33, shielding wire coupler 35) (cable component assembly step).

First of all, a second wiring board 20 (the lower second wiring board 20 in FIG. 16B and FIG. 16C) serving as one of the outer layer substrates is arranged first, whereupon the first wiring board 10 and cable component 30 are juxtaposed and stacked on the second wiring board 20 (as before). Furthermore, a second wiring board 20 (the upper second wiring board 20 in FIG. 16B and FIG. 16C) serving as the other outer layer substrate is stacked on the juxtaposed first wiring board 10 and cable component 30. It should be noted that the mutual alignment can be carried out using a pin-lamination guide (not shown).

Step S14:

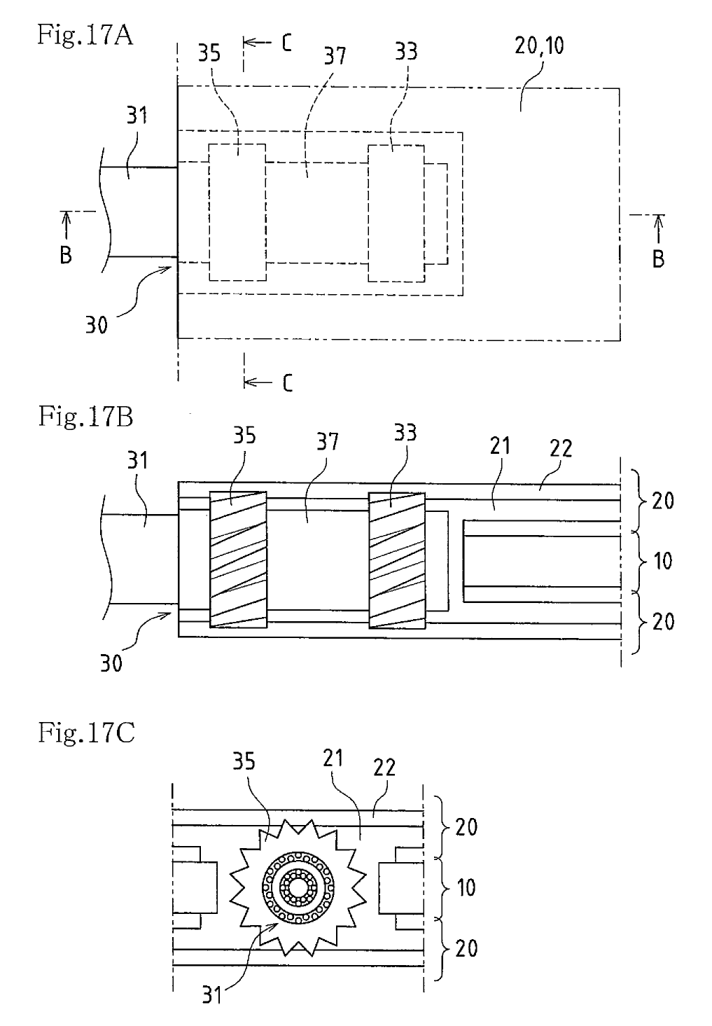

FIG. 17A, FIG. 17B, and FIG. 17C are explanatory diagrams illustrating a state obtained by laminating the cable component, first wiring board, and second wiring boards in the second wiring board lamination step of the cable-type composite printed wiring board fabrication process used in Embodiment 2 of the present invention, where FIG. 17A is a plan elevation, FIG. 17B is a see-through side elevation showing the arrangement in a see-through manner in the direction of arrow B-B in FIG. 17A, and FIG. 17C is an end elevation illustrating the end face of a cross-section taken in the direction of arrow C-C in FIG. 17A.

The second wiring board 20 is laminated onto the first wiring board 10 and cable component 30 (conductor wire coupler 33) such that the conductor wire coupler 33 (conductor wire projections 33p) passes through the second insulating substrate 21 and abuts the second conductor layer 22 (second wiring board lamination step).

Moreover, in the second wiring substrate lamination step, the shielding wire projections 35p, in the same manner as the conductor wire projections 33p, pass through the second insulating substrate 21 and abut against the second conductor layer 22.

The second wiring board lamination step is carried out in vacuum under heating and pressure, in the same manner as in well-known multilayer wiring board lamination processes. As a result of heating and pressure, the conductor wire projections 33p and shielding wire projections 35p can be abutted against and securely connected to the second conductor layer 22.

Since the gap between the first wiring board 10 and the cable component 30 juxtaposed with the cable component window 10w is filled with the second insulating substrate 21 composed of an adhesive agent, the cable component 30 becomes firmly adhered to the first wiring board 10 and second wiring board 20.

Step S17:

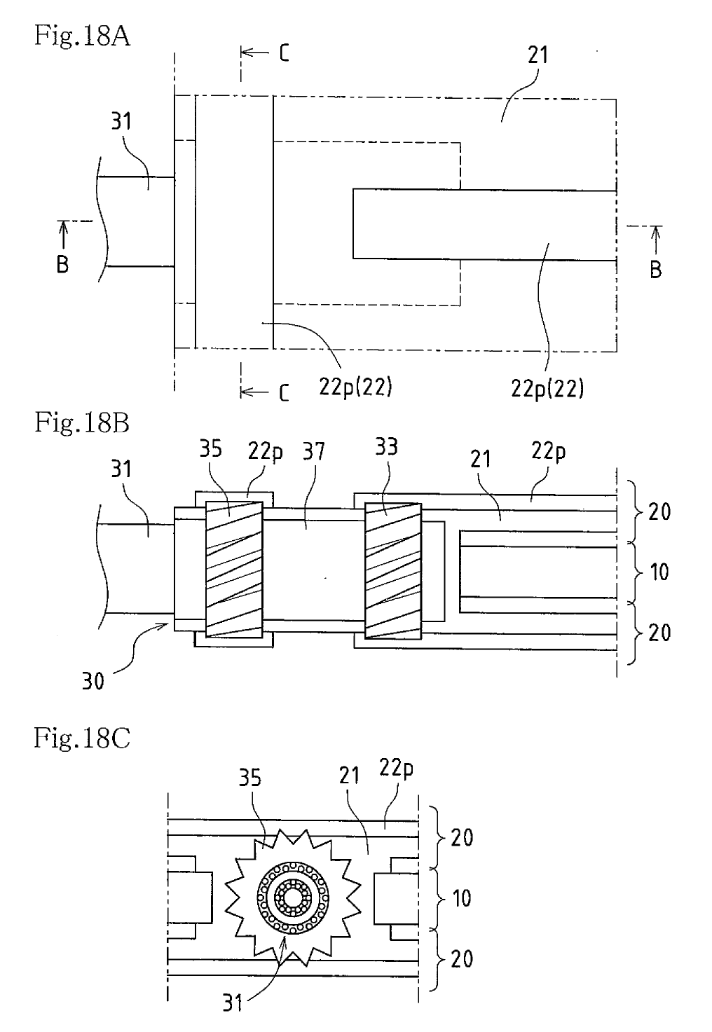

FIG. 18A, FIG. 18B, and FIG. 18C are explanatory diagrams illustrating a state obtained when the second conductor layer pattern is formed in the second conductor layer pattern formation step of the cable-type composite printed wiring board fabrication process used in Embodiment 2 of the present invention, where FIG. 18A is a plan elevation, FIG. 18B is a see-through side elevation showing the arrangement in a see-through manner in the direction of arrow B-B in FIG. 18A, and FIG. 18C is an end elevation illustrating the end face of a cross-section taken in the direction of arrow C-C in FIG. 18A.

The second conductor layer pattern 22p is formed by patterning the second conductor layer 22 (second conductor layer pattern formation step). Namely, the second conductor layer 22 is subjected to patterning to form a second conductor layer pattern 22p abutting against the conductor wire projections 33p (conductor wire coupler 33) (second conductor layer pattern formation step). This makes it possible to connect the conductor wire 31c to the second conductor layer pattern 22p.

The patterning operation can be carried out using well-known techniques. Moreover, appropriate patterning is carried out in other portions that are not shown.

In the second conductor layer pattern formation step, a second conductor layer pattern 22p abutting against the shielding wire projections 35p (shielding wire coupler 35) is formed in the same manner as the conductor wire projections 33p. This makes it possible to connect the shielding wire 31s to, for example, a ground potential location constituted by the second conductor layer pattern 22p.

It should be noted that the first conductor layer 12 and second conductor layer 22 can be interconnected by forming conductive through-holes between the first conductor layer 12 and second conductor layer 22 and, furthermore, forming conductive through-hole conductor establishing electrical continuity through the holes prior to forming the second conductor layer pattern 22p. In other words, well-known techniques can be used to establish an interlayer connection between the first wiring board 10 and second wiring board 20.

Step S18:

FIG. 19A, FIG. 19B, and FIG. 19C are explanatory diagrams illustrating a state obtained when solder resist is formed on the surface of the second wiring boards in the solder resist formation step of the cable-type composite printed wiring board fabrication process used in Embodiment 2 of the present invention, where FIG. 19A is a plan elevation, FIG. 19B is a see-through side elevation showing the arrangement in a see-through manner in the direction of arrow B-B in FIG. 19A, and FIG. 19C is an end elevation illustrating the end face of a cross-section taken in the direction of arrow C-C in FIG. 19A.

A terminal window 40w is formed by coating a solder resist layer 40 on the surface of the second wiring board 20 and appropriately patterning it (solder resist formation step).

The terminal window 40w can be used for connection to the cable component 30 (conductor wire 31c) via the second conductor layer pattern 22p and conductor wire coupler 33.

Upon formation of the solder resist layer 40, the surface of the second conductor layer 22 (second conductor layer pattern 22p) exposed in the terminal window 40w is subjected to anti-corrosion treatment. The anti-corrosion treatment can be carried out using water soluble flux, etc.

After the solder resist formation step, the exterior shape of the first wiring board 10 and second wiring board 20 is subjected to shaping (exterior shaping step). This step results in the fabrication of the cable-type composite printed wiring board in its final form. The exterior shaping step can be carried out an NC router, etc.

The finished cable-type composite printed wiring board is subjected to testing (testing step). As for the type of testing, it can be, for instance, electrical testing, exterior testing, etc.

As described above, the cable-type composite printed wiring board of the present embodiment includes a first wiring board 10 having a first insulating substrate 11 and a first conductor layer pattern 12p, a cable component 30 juxtaposed with the first wiring board 10, and second wiring boards 20, which are laminated onto the first wiring board 10 and have a second insulating substrate 21 and a second conductor layer pattern 22p connected to the cable component 30.

Moreover, in the cable-type composite printed wiring board according to the present embodiment, the cable component 30 includes a cable 31 having a conductor wire 31c and a sheath portion 31h insulating the conductor wire 31c; and a planetary gear-shaped conductor wire coupler 33 which is connected to the conductor wire 31c and has conductor wire projections 31p which, by passing through the second insulating substrate 21, abut against the second conductor layer pattern 22p.

For this reason, the conductor wire projections 33p of the conductor wire coupler 33 can be brought into secure abutment with the second conductor layer pattern 22p and the cable component 30 (conductor wire 31c) can be easily and accurately connected to the second wiring boards 20 (second conductor layer patterns 22p).

Moreover, in the cable-type composite printed wiring board according to the present embodiment, the cable 31 has a shielding wire 31s arranged on the outer periphery of the sheath portion 31h and an outer sheath portion 31f sheathing the shielding wire 31s; and a planetary gear-shaped shielding wire coupler 35 which is connected to the shielding wire 31s and has shielding wire projections 35p which, by passing through the second insulating substrate 21, abut against the second conductor layer pattern 22p.

For this reason, the shielding wire projections 35p of the shielding wire coupler 35 can be brought into secure abutment with the second conductor layer pattern 22p and the cable component 30 (conductor wire 31c) can be easily and accurately connected to the second wiring boards 20.

As described above, the cable-type composite printed wiring board fabrication process according to the present invention includes the steps of: cable component preparation, which involves preparing the cable component 30 by connecting the conductor wire coupler 33 to the conductor wire 31c; first wiring board preparation, which involves preparing the first wiring board 10 having a cable component window 10w used for juxtaposition with the cable component 30; second wiring board preparation, which involves preparing second wiring boards 20, which have a second insulating substrate 21 and a second conductor layer 22 used for forming a second conductor layer pattern 22p formed thereon; cable component assembly, which involves juxtaposing the conductor wire coupler 33 with the cable component window 10w and stacking second wiring boards 20 on the conductor wire coupler 33 and first wiring board 10; second wiring board lamination, which involves laminating the second wiring boards 20 onto the first wiring board 10 and conductor wire coupler 33 such that the conductor wire projections 33p pass through the second insulating substrate 21 and abut against the second conductor layer 22; second conductor layer pattern formation, which involves forming a second conductor layer pattern 22p abutting against the conductor wire projections 33p by patterning the second conductor layer 22; and exterior shaping, which involves shaping the exterior of the first wiring board 10 and second wiring boards 20.

For this reason, due to the fact that the conductor wire coupler 33 (conductor wire projections 33p) connected to the conductor wire 31c can be easily and accurately brought into abutment with the second conductor layer pattern 22p, a cable-type composite printed wiring board can be manufactured, in which the cable component 30 (conductor wire 31c) and second conductor layer pattern 22p can be easily and accurately connected, a reduction in size and thickness, as well as free spatial configuration, are made possible, signal transmission can be effected in a dependable manner, and the reliability of connection between the cable component 30 and second conductor layer pattern 22p is high.

Moreover, in the cable-type composite printed wiring board fabrication process according to the present embodiment, the cable 31 has a shielding wire 31s arranged on the outer periphery of the sheath portion 31h and an outer sheath portion 31f sheathing the shielding wire 31s; and the cable component 30 includes a planetary gear-shaped shielding wire coupler 35 which is connected to the shielding wire 31s and has shielding wire projections 35p which, by passing through the second insulating substrate 21, abut against the second conductor layer pattern 22p, and, in the cable component preparation step, the shielding wire coupler 35 is connected to the shielding wire 31s; in the cable component assembly step, the shielding wire coupler 35 is arranged in the cable component window 10w and a second wiring board 20 is stacked on the shielding wire coupler 35; in the second wiring board lamination step, the shielding wire projections 35p pass through the second insulating substrate 21 and abut the second conductor layer 22, and in the second conductor layer pattern formation step, the second conductor layer pattern 22p abutting against the shielding wire projections 35p is formed by patterning the second conductor layer 22.

For this reason, due to the fact that the shielding wire 31s can be easily and accurately connected to the second conductor layer pattern 22p, it becomes possible to fabricate a cable-type composite printed wiring board including a cable component 30 in which the reliability of the connection between the cable component 30 (shielding wire 31s) and the second conductor layer pattern 22p is improved, the shielding properties are enhanced, and which has superior high-frequency characteristics.

### Embodiment 3

The electronic device of the present embodiment (not shown) is an electronic device having the cable-type composite printed wiring board according to Embodiment 2 installed therein. In other words, it is an electronic device having installed therein a cable-type composite printed wiring board with the cable component 30 connected thereto.

Because the cable-type composite printed wiring board permits size reduction, thickness reduction and free spatial configuration matching various housing shapes, an electronic device can be implemented that achieves a reduction in the size and thickness of the housing, makes it possible to impart it with the desired shape, and provides high reliability of connection.

It should be noted that the such electronic devices include communication terminals such as mobile phones, which require superior electrical characteristics at high frequencies and a reduction in size and weight.

The present invention can be embodied and practiced in other different forms without departing from the spirit and essential characteristics thereof. Therefore, the above-described working examples are considered in all respects as illustrative and not restrictive. The scope of the invention is indicated by the appended claims rather than by the foregoing description. All variations and modifications falling within the equivalency range of the appended claims are intended to be embraced therein.

1. A cable-type composite printed wiring board comprising: a first wiring board having a first insulating substrate and a first conductor layer pattern; a cable component juxtaposed with the first wiring board; and second wiring boards having a second conductor layer pattern connected to the cable component and a second insulating substrate laminated onto the first wiring board,
wherein the cable component comprises a cable having a conductor wire and a sheath portion insulating the conductor wire, and a planetary gear-shaped conductor wire coupler connected to the conductor wire and having conductor wire projections which, by passing through the second insulating substrate, abut against the second conductor layer pattern.

2. The cable-type composite printed wiring board according to claim 1, wherein the apices of the conductor wire projections are disposed at positions symmetrical with respect to the bottom portions on both sides of the conductor wire projections.

3. The cable-type composite printed wiring board according to claim 1, wherein the number of the conductor wire projections is an even number.

4. The cable-type composite printed wiring board according to claim 1, wherein the conductor wire projections are disposed such that the angle of intersection of the plane defined by the conductor wire projections and the plane of the second conductor layer pattern is not more than 90 degrees.

5. The cable-type composite printed wiring board according to claim 3, wherein the number of the conductor wire projections is 6 or more.

6. The cable-type composite printed wiring board according to claim 1, wherein the conductor wire coupler is shaped as a helical gear.

7. The cable-type composite printed wiring board according to claim 6, wherein the obliqueness of the helical gear-shaped apices of the conductor wire coupler with respect to the thickness of the conductor wire coupler in the length direction of the conductor wire is equal to or greater than the inter-apex pitch.

8. The cable-type composite printed wiring board according to claim 1, wherein the conductor wire projections are triangular in shape.

9. The cable-type composite printed wiring board according to claim 1, wherein there is formed a resin encapsulation portion encapsulating the end face of the conductor wire coupler in the length direction of the conductor wire.

10. The cable-type composite printed wiring board according to claim 9, wherein the resin encapsulation portion has a true circular shape.

11. The cable-type composite printed wiring board according to claim 9, wherein the outer periphery of the resin encapsulation portion is disposed closer to the conductor wire than to the bottom portions of the conductor wire projections.

12. The cable-type composite printed wiring board according to claim 1, the cable has a shielding wire arranged on the outer periphery of the sheath portion and an outer sheath portion sheathing the shielding wire, and the cable component comprises a planetary gear-shaped shielding wire coupler connected to the shielding wire and having shielding wire projections which, by passing through the second insulating substrate, abut against the second conductor layer pattern.

13. The cable-type composite printed wiring board according to claim 12, wherein the apices of the shielding wire projections are disposed at positions symmetrical with respect to the bottom portions on both sides of the shielding wire projections.

14. The cable-type composite printed wiring board according to claim 12, wherein the number of the shielding wire projections is an even number.

15. The cable-type composite printed wiring board according to claim 12, wherein the shielding wire projections are disposed such that the angle of intersection of the plane defined by the shielding wire projections and the plane of the second conductor layer pattern is not more than 90 degrees.

16. The cable-type composite printed wiring board according to claim 14, wherein the number of the shielding wire projections is 6 or more.

17. The cable-type composite printed wiring board according to claim 12, wherein the shielding wire coupler is shaped as a helical gear.

18. The cable-type composite printed wiring board according to claim 17, wherein the obliqueness of the helical gear-shaped apices of the shielding wire coupler with respect to the thickness of the shielding wire coupler in the length direction of the conductor wire is equal to or greater than the inter-apex pitch.

19. The cable-type composite printed wiring board according to claim 12, wherein the shielding wire projections are triangular in shape.

20. The cable-type composite printed wiring board according to claim 12, wherein there is formed a resin encapsulation portion encapsulating the end face of the shielding wire coupler in the length direction of the conductor wire.

21. The cable-type composite printed wiring board according to claim 20, wherein the resin encapsulation portion has a true circular shape.

22. The cable-type composite printed wiring board according to claim 20, wherein the outer periphery of the resin encapsulation portion is disposed closer to the shielding wire than to the bottom portions of the shielding wire projections.

23. A cable component for use in a cable-type composite printed wiring board comprising: a first wiring board having a first insulating substrate and a first conductor layer pattern, second wiring boards that have a second insulating substrate and a second conductor layer pattern and are laminated onto the first wiring board, and a cable component juxtaposed with the first wiring board and connected to the second conductor layer pattern,
wherein the cable component comprises:
a cable having a conductor wire and a sheath portion insulating the conductor wire, and
a planetary gear-shaped conductor wire coupler connected to the conductor wire and having conductor wire projections which, by passing through the second insulating substrate, abut against the second conductor layer pattern.

24. The cable component according to claim 23,
wherein the cable has a shielding wire arranged on the outer periphery of the sheath portion and an outer sheath portion sheathing the shielding wire and comprises a planetary gear-shaped shielding wire coupler connected to the shielding wire and having shielding wire projections which, by passing through the second insulating substrate, abut against the second conductor layer pattern.

25. An electronic device equipped with a cable-type composite printed wiring board having a cable component connected thereto,
wherein the cable-type composite printed wiring board is the cable-type composite printed wiring board according to claim 1.
